(19) United States
(12) Patent Application Publication
(10) Pub. No.: US 2026/0182217 A1
(43) Pub. Date: Jun. 25, 2026

(54) DISPLAY PANEL, ELECTRONIC DEVICE INCLUDING THE SAME, AND METHOD FOR MANUFACTURING THE DISPLAY PANEL

(71) Applicant: Samsung Display Co., Ltd., Yongin-si (KR)

(72) Inventors: YOONSEOK KA, Yongin-si (KR); Yuki HIRAYAMA, Yongin-si (KR)

(21) Appl. No.: 19/413,769

(22) Filed: Dec. 9, 2025

(30) Foreign Application Priority Data
Dec. 19, 2024 (KR) 10-2024-0191397

(51) Int. Cl. H10K 59/80; H10K 59/12

(52) U.S. Cl. CPC H10K 59/873; H10K 59/1201

(57) ABSTRACT

A display panel includes a light emitting element including a first electrode, a hole transport region, an emission layer, an electron transport region, and a second electrode, which are stacked in sequence, and an encapsulation layer on the light emitting element and including at least one inorganic encapsulation film and at least one organic encapsulation film. The emission layer includes a plurality of quantum dots, the electron transport region includes a plurality of metal oxide particles, and a carboxyl derivative is coupled to at least a portion of the quantum dots and/or at least a portion of the metal oxide particles.

### CROSS-REFERENCE TO RELATED APPLICATION

The present application claims priority to and the benefit of Korean Patent Application No. 10-2024-0191397, filed on Dec. 19, 2024, in the Korean Intellectual Property Office, the entire content of which is incorporated herein by reference.

### BACKGROUND

### 1. Field

One or more embodiments of the present disclosure relate to a display panel, an electronic device, and a method for manufacturing the display panel. For example, one or more embodiments of the present disclosure relate to a display panel with improved efficiency and lifespan, in which a defect in a light emitting element of the display panel is passivated by addition of an additive, an electronic device including such a display panel, and a method for manufacturing such a display panel.

### 2. Description of Related Art

Multimedia electronic devices such as televisions, mobile phones, tablet computers, navigation devices, game consoles, and/or wearable devices may include display panel(s) which display images. In such display panels, self-emissive light emitting elements are generally used. These self-emissive light emitting elements may include (in each of which) a light emitting material including an organic compound, a quantum dot, and/or the like in an emission layer arranged between electrodes opposite to (e.g., facing) each other, and emit light to accomplish display (e.g., display of images).

For the application of light-emitting elements in display panels, improvements in luminance efficiency and lifespan of the light emitting element are desired or required to enhance/improve display quality of the display panel and an electronic device including the display panel.

### SUMMARY

One or more aspects of embodiments of the present disclosure are directed toward a display panel that has excellent or suitable luminance efficiency and improved lifespan characteristics, and an electronic device including the display panel.

One or more aspects of embodiments of the present disclosure are directed toward a display panel with excellent or suitable reliability in which an organic acid additive is used to perform an aging treatment of compensating for a defective portion in a light emitting element of the display panel.

One or more aspects of embodiments of the present disclosure are directed toward a method for manufacturing a display panel including a light emitting element with improved efficiency and lifespan.

Additional aspects will be set forth in part in the description which follows and, in part, will be apparent from the description, or may be learned by practice of the presented embodiments.

According to one or more embodiments of the present disclosure, a display panel includes a light emitting element including a first electrode, a hole transport region, an emission layer, an electron transport region, and a second electrode, which are stacked in sequence, and an encapsulation layer on (e.g., arranged on) the light emitting element and including at least one inorganic encapsulation film and at least one organic encapsulation film. The emission layer includes a plurality of quantum dots, and the electron transport region includes a plurality of metal oxide particles. A carboxyl derivative is coupled to at least a portion of the quantum dots and/or at least a portion of the metal oxide particles.

In one or more embodiments, the electron transport region may include a modified metal oxide particle in which the carboxyl derivative is coupled to an outer edge of the metal oxide particle.

In one or more embodiments, each of the quantum dots of the emission layer may include a core and a shell around (e.g., surrounding) the core, and the emission layer may include a modified quantum dot including the carboxyl derivative coupled to the shell.

In one or more embodiments, the carboxyl derivative may be derived from an organic acid additive represented by any one selected from among A1 to A12:

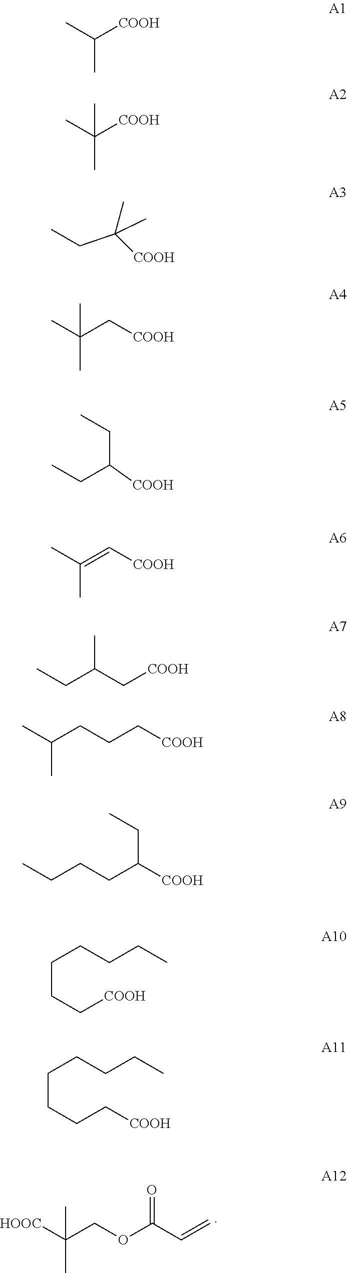

In one or more embodiments, the at least one organic encapsulation film may further include the organic acid additive.

In one or more embodiments, the at least organic encapsulation film may include, as a base part, a polymer derived and polymerized from an acrylate-based monomer.

In one or more embodiments, the at least one organic encapsulation film may include a polymer base part polymerized from an organic layer mixture including an acrylate-based monomer and an organic acid additive, the emission layer may include a modified quantum dot to which the carboxyl derivative derived from the organic acid additive is coupled, and the electron transport region may include a modified metal oxide particle to which the carboxyl derivative derived from the organic acid additive is coupled.

In one or more embodiments, the encapsulation layer may include a first inorganic encapsulation film directly on (e.g., arranged on) the light emitting element, an organic encapsulation film on (e.g., arranged on) the first inorganic encapsulation film, and a second inorganic encapsulation film on (e.g., arranged on) the organic encapsulation film.

In one or more embodiments of the present disclosure, an electronic device includes a display device including a display panel which is configured to display an image, and the display panel includes a base layer, a circuit layer on (e.g., arranged on) the base layer, a display layer on (e.g., arranged on) the circuit layer and including a plurality of light emitting elements, and an encapsulation layer on (e.g., arranged on) the display layer and including at least one inorganic encapsulation film and at least one organic encapsulation film. Each of the light emitting elements includes a first electrode, a hole transport region, an emission layer, an electron transport region, and a second electrode, which are stacked in sequence. The emission layer includes a plurality of quantum dots, the electron transport region includes a plurality of metal oxide particles, and a carboxyl derivative is coupled to at least a portion of the quantum dots and/or at least a portion of the metal oxide particles.

In one or more embodiments, the at least one organic encapsulation film may include a polymer base part polymerized from an organic layer mixture including an acrylate-based monomer and an organic acid additive, the emission layer may include a modified quantum dot to which the carboxyl derivative derived from the organic acid additive is coupled, and the electron transport region may include a modified metal oxide particle to which the carboxyl derivative derived from the organic acid additive is coupled.

In one or more embodiments, the organic acid additive may have an acid dissociation constant (pKa) of about 4.8 or higher and have a volatile onset temperature of lower than about 90° C., and a difference (Ra) in Hansen solubility parameter between the organic acid additive and the acrylate-based monomer may be less than about 12.

In one or more embodiments, the electronic device may further include at least one of a processor, a memory, or a power module.

In one or more embodiments, the electronic device may include the display panel and be an image display device, a wearable device, or a device for vehicle.

According to one or more embodiments of the present disclosure, a method for manufacturing a display panel includes forming a light emitting element in which a first electrode, a hole transport region, an emission layer, an electron transport region, and a second electrode are stacked in sequence, forming a first inorganic encapsulation film on the light emitting element, providing (e.g., applying), onto the first inorganic encapsulation film, an organic layer mixture including an organic acid additive having at least one carboxyl group, and an acrylate-based monomer, ultraviolet curing the organic layer mixture to form an organic encapsulation film, forming a second inorganic encapsulation film on the organic encapsulation film, and performing a heat treatment at a temperature of about 80° C. to about 120° C.

In one or more embodiments, the organic acid additive may have an acid dissociation constant (pKa) of about 4.8 or higher and have a volatile onset temperature of lower than about 90° C.

In one or more embodiments, a difference (Ra) in Hansen solubility parameter between the organic acid additive and the acrylate-based monomer may be less than about 12.

In one or more embodiments, the organic acid additive may be represented by any one selected from among A1 to A12:

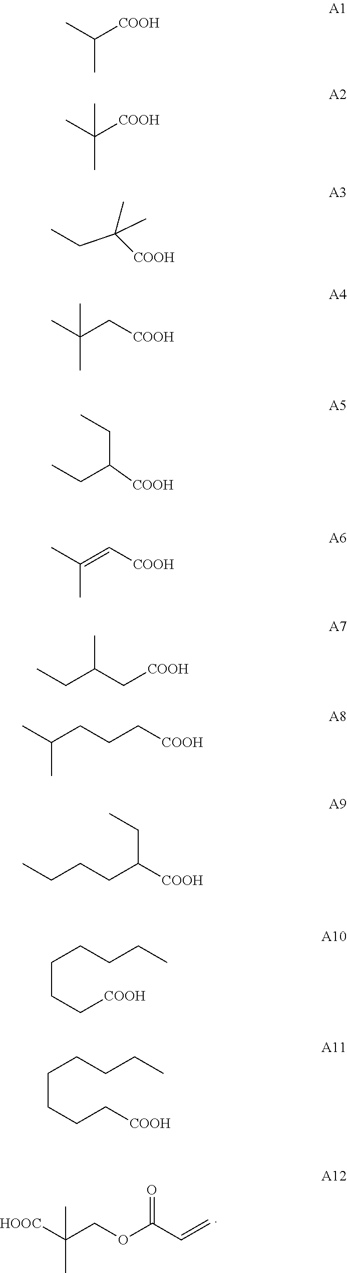

In one or more embodiments, the acrylate-based monomer may include at least one of monomer compound M1 or monomer compound M2:

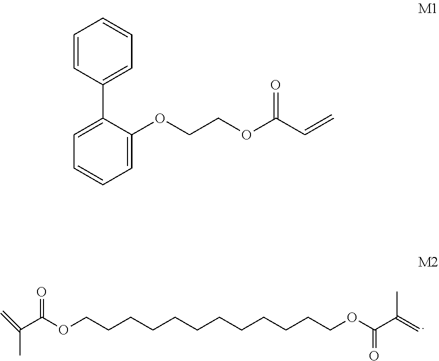

In one or more embodiments, the performing of the heat treatment may include volatilizing the organic acid additive to move the organic acid additive toward the emission layer and the electron transport region.

In one or more embodiments, an amount of the organic acid additive may be about 5 wt % to about 30 wt % on the basis of a weight of the acrylate-based monomer in the organic layer mixture.

In one or more embodiments, in the forming of the light emitting element, the emission layer may include a plurality of quantum dots, each of which includes a core and a shell around (e.g., surrounding) the core, the electron transport region may include a plurality of metal oxide particles, and at least a portion of the quantum dots and/or at least a portion of the metal oxide particles may have an oxygen vacancy defect.

In one or more embodiments, the performing of the heat treatment may include passivating the oxygen vacancy defect by utilizing a carboxyl derivative derived from the organic acid additive.

In one or more embodiments, the performing of the heat treatment may include at least one of coupling the carboxyl derivative to the quantum dot having the oxygen vacancy defect to form a modified quantum dot, or coupling the carboxyl derivative to the metal oxide particle having the oxygen vacancy defect to form a modified metal oxide particle.

In one or more embodiments, in the forming of the organic encapsulation film, the organic acid additive may be included in the organic encapsulation film, and in the performing of the heat treatment, the organic acid additive may be moved in a fume state to at least one of the emission layer or the electron transport region, and the carboxyl derivative derived from the organic acid additive may be coupled to at least one of a portion of the quantum dots of the emission layer or a portion of the metal oxide particles of the electron transport region.

For example, by incorporating an organic acid additive into the encapsulation structure and leveraging its migration and chemical interaction during heat treatment, the disclosed embodiments enable effective passivation of oxygen vacancy defects in quantum dots and metal oxide particles. This results in improved luminance efficiency, extended operational lifespan, and enhanced defect tolerance of light-emitting elements, thereby contributing to the development of high-performance electronic devices with advanced and reliable display capabilities.

### BRIEF DESCRIPTION OF DRAWINGS

The accompanying drawings are included to provide a further understanding of the present disclosure, and are incorporated in and constitute a part of this disclosure. The drawings illustrate embodiments of the present disclosure and, together with the description, serve to explain principles of the disclosure. Above and/or other aspects of the disclosure should become apparent and appreciated from the following description of embodiments taken in conjunction with the accompanying drawings. In the drawings:

FIG. 1 is a block diagram of an electronic device according to one or more embodiments of the present disclosure;

FIG. 2 illustrates schematic views of electronic devices according to one or more embodiments of the present disclosure;

FIG. 3 is a perspective view of an electronic device according to one or more embodiments of the present disclosure;

FIG. 4 is a perspective view of a display device according to one or more embodiments of the present disclosure;

FIG. 5 is a cross-sectional view of a display device according to one or more embodiments of the present disclosure;

FIG. 6 is a cross-sectional view of a portion of a display device according to one or more embodiments of the present disclosure;

FIG. 7 is a cross-sectional view of a light emitting element according to one or more embodiments of the present disclosure;

FIG. 8A is a schematic view illustrating a modified electron transport material according to one or more embodiments of the present disclosure;

FIG. 8B is a schematic view illustrating a modified quantum dot according to one or more embodiments of the present disclosure;

FIG. 9 is a cross-sectional view of a portion of a display panel according to one or more embodiments of the present disclosure;

FIG. 10A is a schematic view illustrating a hole movement characteristic in a typical light emitting element;

FIG. 10B is a schematic view illustrating a hole movement characteristic in a light emitting element according to one or more embodiments of the present disclosure;

FIG. 11 is a flowchart illustrating a method for manufacturing a display panel according to one or more embodiments of the present disclosure;

FIGS. 12A-12E are each a view illustrating an example of a step (e.g., act or task) of a method for manufacturing a display panel according to one or more embodiments of the present disclosure; and

FIG. 13 is a graph illustrating luminance characteristics of an embodiment and a comparative example of the present disclosure.

### DETAILED DESCRIPTION

Embodiments of the present disclosure may be modified and practiced in many alternate forms, and thus example embodiments will be exemplified in the drawings and described in more detail. It should be understood, however, that it is not intended to limit the disclosure to the particular forms disclosed, but rather, is intended to cover all modifications, equivalents, and alternatives falling within the spirit and scope of the disclosure.

In this disclosure, it will be understood that if (e.g., when) an element (or a region, a layer, a portion, and/or the like) is referred to as being “on”, “connected to” or “coupled to” another element, it may be directly arranged on, connected to, or coupled to the other element, or one or more other elements may be arranged therebetween. In contrast, “directly on” may refer to that there are no additional intervening elements or layers between the element or layer and the other element or layer. In addition, if (e.g., when) a layer, a film, a region, a plate, and/or the like is referred to as being “under” or “below” another part, it may be “directly under” the other part, or one or more intervening layers may be present therebetween. Also, if (e.g., when) an element is referred to as being arranged “on” another element, it may be arranged under the other element.

Like reference numerals or symbols refer to like elements throughout the disclosure, and duplicative descriptions thereof may not be provided for conciseness. In the drawings, the thickness, ratio, and size of the elements may be exaggerated for effectively describing the technical contents. As used herein, the term “and/or” or “or” or “/” may include any and all combinations of one or more of the associated listed elements.

It will be understood that, although the terms “first”, “second”, and/or the like may be used herein to describe one or more suitable elements, the elements are not to be limited by these terms. These terms are only used to distinguish one element, component, region, layer, or section from another element, component, region, layer, or section. For instance, a first element, component, region, layer, or section discussed could be termed a second element, component, region, layer, or section without departing from the scope and teachings of the disclosure. Similarly, a second element, component, region, layer, or section could be termed a first element, component, region, layer, or section. In this disclosure, the singular expressions “a”, “an” and “the” are intended to include the plural forms as well, unless the context clearly indicates otherwise. Further, the use of “may” when describing embodiments of the present disclosure refers to “one or more embodiments of the present disclosure.”

In addition, the terms “below”, “under”, “on the lower side”, “above”, “over”, “on the upper side”, and/or the like may be used to describe the relationships between the elements illustrated in the drawings. These terms are relative concepts and are described on the basis of the directions indicated in the drawings.

It will be further understood that the terms “comprise(s)/include(s)/has (have)” and/or “comprising/including/having”, if (e.g., when) used in this disclosure, specify the presence of stated features, numbers, steps, operations, elements, components, or combinations thereof, but do not preclude the possibility of the presence or addition of one or more other features, numbers, steps, operations, elements, components, and/or combinations thereof. Additionally, the terms “comprise(s)/comprising,” “include(s)/including,” “has (have)/having”, or other similar terms include or support the terms “consisting of” and “consisting essentially of,” indicating the presence of stated features, numbers, steps, operations, parts, and/or components, without or essentially without the presence of other features, numbers, steps, operations, parts, components, and/or combinations thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a display panel according to one or more embodiments, an electronic device according to one or more embodiments, and a method for manufacturing the display panel according to one or more embodiments will be described in more detail with reference to the drawings.

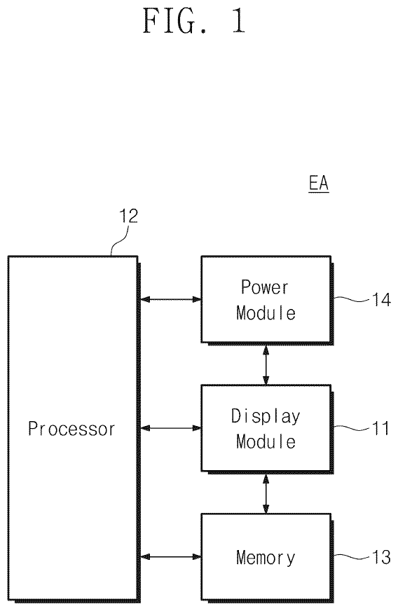

FIG. 1 is a block diagram of an electronic device according to one or more embodiments of the present disclosure. Referring to FIG. 1, an electronic device EA according to one or more embodiments may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may store data information necessary for an operation of the processor 12 and/or the display module 11. When the processor 12 executes an application stored in the memory 13, an image data signal and/or an input control signal may be transmitted to the display module 11, and the display module 11 may process the received signal and output image information through a display screen. The display module 11 may include a display panel which displays an image.

The power module 14 may include a power supply module such as a power adapter or a battery device, and a power conversion module which converts the power supplied by the power supply module and generates power necessary for an operation of the electronic device EA.

At least one of the components of the electronic device EA described above may be included in a display device including the display panel according to one or more embodiments, described later. In addition, some of individual modules included as functional in one module may be included in the display device, and others may be provided separately from the display device. For example, the display device may include the display module 11, and the processor 12, the memory 13, and the power module 14 may be provided not in the display device but in another type (kind) of device in the electronic device EA.

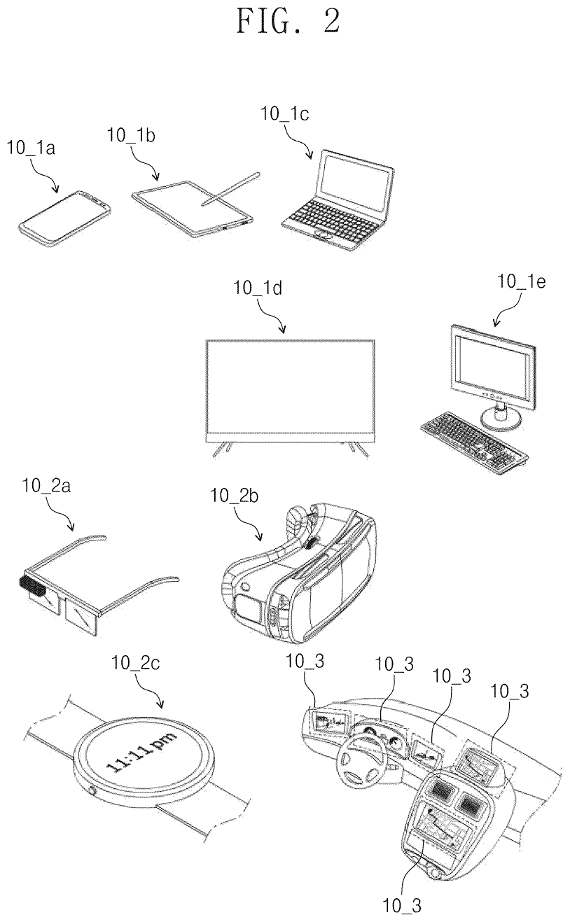

FIG. 2 illustrates schematic views of electronic devices according to one or more embodiments of the present disclosure.

Referring to FIG. 2, one or more suitable electronic devices each including a display device according to one or more embodiments may include not only an electronic device for image display, e.g., a smartphone 10_1a, a tablet computer (PC) 10_1b, a laptop computer 10_1c, TV 10_1d, and a monitor for a desk computer 10_1e, but also a wearable electronic device including a display module, e.g., smart glasses 10_2a, a head mounted display 10_2b, and a smart watch 10_2c, and an electronic device for vehicle 10_3 including a display module, e.g., a vehicle instrument panel, a center fascia, a center information display (CID) arranged on a dashboard, and a room mirror display.

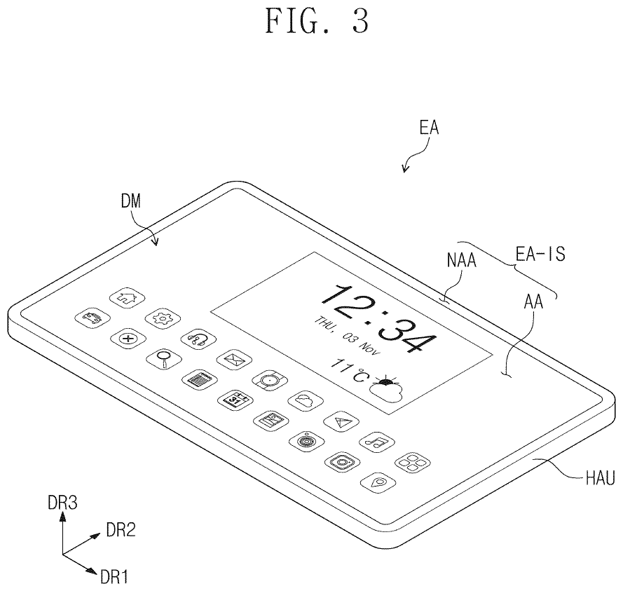

FIG. 3 is a perspective view illustrating an electronic device according to one or more embodiments of the present disclosure.

An electronic device EA according to one or more embodiments may include a display device DM which displays an image through a display surface EA-IS. The display device DM may be accommodated and arranged in a housing HAU. The electronic device EA may include the display device DM and a controller which controls an operation of the display device DM.

In one or more embodiments, the display surface EA-IS of the electronic device EA may have a rectangular shape having long sides extending in a first direction DR1 and short sides extending in a second direction DR2 crossing the first direction DR1 if (e.g., when) viewed on a plane (i.e., in plan view). However, embodiments of the disclosure are not limited thereto, and the display surface EA-IS may have one or more suitable shapes such as a circular shape or a polygonal shape.

In the present disclosure, a third direction DR3 may be defined as a direction substantially perpendicular to a plane defined by the first direction DR1 and the second direction DR2. A front surface (or top surface) and a rear surface (or bottom surface) of each of members constituting the electronic device EA may oppose each other in the third direction DR3, and a normal direction to each of the front surface and the rear surface may be substantially parallel to the third direction DR3. A separation distance between the front surface and the rear surface, which is defined along the third direction DR3, may correspond to a thickness of the member.

The term “on a plane” or “in plan view” used herein may be defined as being in a state if (e.g., when) viewed in the third direction DR3. For example, the term “on a plane” may be described on the basis of a plane defined by the first direction DR1 and the second direction DR2 together. The term “on a cross-section” used herein may be defined as being in a state if (e.g., when) viewed in the first direction DR1 or the second direction DR2. However, directions indicated by the first to third directions DR1, DR2, and DR3 are relative concepts and may be changed to other directions.

FIG. 3 illustrates a tablet terminal as an example of the electronic device EA. Electronic modules, a camera module, a power module, and/or the like, which are mounted on a main board, may be arranged together with a display device DM in a bracket/the housing HAU and/or the like, thereby constituting the tablet terminal. However, embodiments of the present disclosure are not limited thereto, for example, the display device DM and a display panel according to one or more embodiments, described later, may be applied to a large-sized electronic device such as a television, a monitor, or an outdoor billboard, and also a small and medium-sized electronic device such as a personal computer, a notebook computer, a personal digital assistant, a vehicle navigation unit, a game console, a smartphone, a tablet computer, a smart watch, and a camera. These are just provided as examples, and the display device DM according to one or more embodiments may be employed as other electronic devices unless departing from the present disclosure. In one or more embodiments, the electronic device EA including the display device DM may be also referred to as a display device.

In one or more embodiments, the electronic device EA is illustrated as including the display device DM having a flat display surface, but the present disclosure is not limited thereto. In one or more embodiments, the electronic device EA may include a curved display surface or a three-dimensional display surface. For example, the three-dimensional display surface may include a plurality of display areas oriented in different directions and include a bent display surface. The electronic device EA according to these embodiments may be a flexible electronic device. The flexible electronic device may be a foldable electronic device capable of folding.

As illustrated in FIG. 3, the display surface EA-IS may include an active area AA where an image is displayed, and a bezel area NAA adjacent to the active area AA. The bezel area NAA is an area where an image is not displayed. FIG. 3 illustrates icon images as one example of the image. The active area AA may be also referred to as a display area of the display device DM, and the bezel area NAA may be also referred to as a non-display area of the display device DM.

As illustrated in FIG. 3, the active area AA may have a substantially rectangular shape. The “substantially rectangular shape” includes not only a rectangular shape in terms of mathematics, but also a rectangular shape in which not a vertex but a curved boundary is defined in a vertex area (or corner area).

The bezel area NAA may surround (e.g., be around) the active area AA. However, a shape of the bezel area NAA is not limited thereto and may be changed. For example, in one or more embodiments, the bezel area NAA may be arranged at only one side of the active area AA.

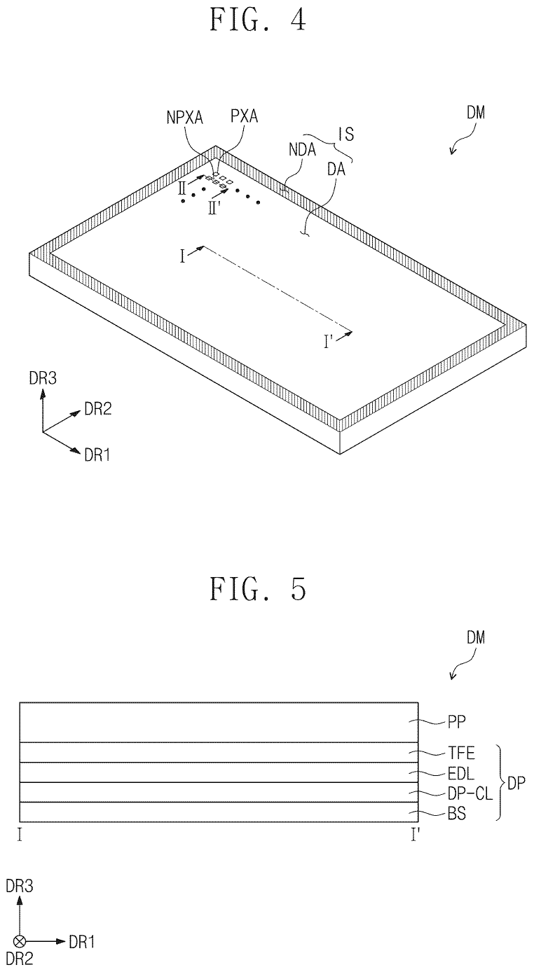

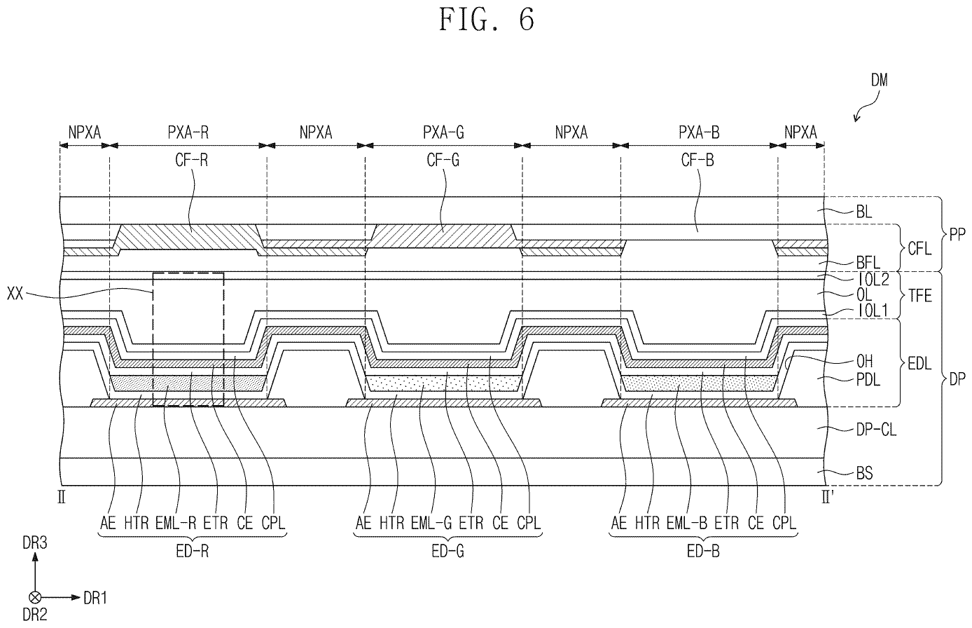

FIG. 4 is a perspective view of a display device according to one or more embodiments of the present disclosure. FIG. 5 is a cross-sectional view of a display device according to one or more embodiments. FIG. 6 is a cross-sectional view illustrating the display device according to one or more embodiments in more detail. FIG. 5 may be a cross-sectional view corresponding to the line I-l′ in FIG. 4 according to one or more embodiments, and FIG. 6 may be a cross-sectional view corresponding to the line II-II′ in FIG. 4 according to one or more embodiments.

Referring to FIG. 4, a display device DM may include a display surface IS, and the display device DM may display an image through the display surface IS. The display surface IS of the display device DM may correspond to the display surface EA-IS of the electronic device EA.

The display surface IS may include a display area DA and a non-display area NDA. A plurality of pixel areas PXA may be arranged in the display area DA. A peripheral area NPXA is arranged around each of the pixel areas PXA. The pixel areas PXA may be referred to as light emitting areas, and the peripheral area NPXA may be referred to as a non-light emitting area.

In one or more embodiments, the pixel areas PXA may not be arranged in the non-display area NDA of the display surface IS, and the non-display area NDA may be around (e.g., surround) the display area DA. However, embodiments of the present disclosure are not limited thereto, for example, in one or more embodiments, the non-display area NDA may not be provided or be arranged at only one side of the display area DA.

Referring to FIG. 5 and FIG. 6, a display device DM according to one or more embodiments may include a display panel DP. The display panel DP may be a component that substantially generates image data. The display panel DP according to one or more embodiments may be a component that is included in the electronic device EA (see FIG. 3) according to one or more embodiments and displays an image. The display panel DP according to one or more embodiments may be an emissive display panel. In one or more embodiments, the display panel DP may include an inorganic luminous body such as quantum dots.

The display panel DP may include a base layer BS, a circuit layer DP-CL, a display layer EDL, and an encapsulation layer TFE, which are stacked in sequence in a third directional axis DR3 direction (i.e., in the third direction DR3 or in a thickness direction).

The display layer EDL may include light emitting elements ED-R, ED-G, and ED-B. A plurality of pixel areas PXA may be areas which emit light generated from the light emitting elements ED-R, ED-G, and ED-B, respectively.

The encapsulation layer TFE may be directly arranged on the display layer EDL. The encapsulation layer TFE may cover the light emitting elements ED-R, ED-G, and ED-B of the display layer EDL.

The display device DM according to one or more embodiments may further include an optical member PP. The optical member PP may be arranged on the display panel DP. The optical member PP may be arranged on the display panel DP and control reflected light from the display panel DP due to external light.

The display device DM according to one or more embodiments may include the plurality of pixel areas PXA repeatedly arranged over the display area DA. The pixel areas PXA in the display device DM according to one or more embodiments may be arranged in the form of a stripe on a plane. Referring to FIG. 4, the plurality of pixel areas PXA may be arranged along a first directional axis DR1 (i.e., first direction DR1) or a second directional axis DR2 (i.e., second direction DR2). However, embodiments of the present disclosure are not limited thereto, for example, an arrangement shape of the pixel areas PXA may include a PenTile (PENTILE®) arrangement shape (for example, an RGBG matrix, an RGBG structure, or an RGBG matrix structure), or a diamond (Diamond Pixel™) arrangement shape (e.g., red, blue, and green (RGB) light-emitting regions arranged in the shape of diamonds). PENTILE® is a duly registered trademark of Samsung Display Co., Ltd. Diamond Pixel™ is a trademark of Samsung Display Co., Ltd.

In addition, although all the pixel areas PXA illustrated in FIG. 4 and/or the like have similar planar surface areas, embodiments of the present disclosure are not limited thereto, and the planar surface areas of the pixel areas PXA may each be different according to wavelength regions of their emitted light.

Referring to FIG. 4 and FIG. 6, in one or more embodiments, the pixel areas PXA may include first to third pixel areas PXA-R, PXA-G, and PXA-B. In the display device DM according to one or more embodiments, the first to third pixel areas PXA-R, PXA-G, and PXA-B may be areas which are separated from one another on a plane and emit light in different wavelength regions from one another.

In addition, the display device DM according to one or more embodiments may include a peripheral area NPXA arranged around each of the first to third pixel areas PXA-R, PXA-G, and PXA-B. The peripheral area NPXA sets a boundary between the first to third pixel areas PXA-R, PXA-G, and PXA-B. The peripheral area NPXA may be around (e.g., surround) each of the first to third pixel areas PXA-R, PXA-G, and PXA-B. A structure, for example, a pixel defining layer PDL, which prevents color mixture between the first to third pixel areas PXA-R, PXA-G, and PXA-B, may be arranged in the peripheral area NPXA to overlap the peripheral area NPXA.

The first to third pixel areas PXA-R, PXA-G, and PXA-B may be areas divided by the pixel defining layer PDL. The peripheral area NPXA is an area between neighboring areas of the first to third pixel areas PXA-R, PXA-G, and PXA-B, and may be an area corresponding to the pixel defining layer PDL.

The first to third pixel areas PXA-R, PXA-G, and PXA-B may be areas which emit light generated from first to third light emitting elements ED-R, ED-G, and ED-B, respectively. The first to third pixel areas PXA-R, PXA-G, and PXA-B may be spaced from (e.g., spaced apart from) one another on a plane.

The pixel defining layer PDL may separate the first to third light emitting elements ED-R, ED-G, and ED-B. Respective emission layers EML-R, EML-G, and EML-B of the first to third light emitting elements ED-R, ED-G, and ED-B may be each arranged within a pixel opening portion OH defined in the pixel defining layer PDL, and be separated from one another.

The pixel defining layer PDL may include a polymer resin. For example, the pixel defining layer PDL may include a polyacrylate-based resin or a polyimide-based resin. In one or more embodiments, the pixel defining layer PDL may further include an inorganic material in addition to the polymer resin. The pixel defining layer PDL may include a light absorbing material, or may include a black pigment and/or a black dye. The pixel defining layer PDL including the black pigment and/or the black dye may achieve a black pixel defining layer. In one or more embodiments, when the pixel defining layer PDL is formed, a carbon black and/or the like may be used as the black pigment or the black dye, but embodiments of the present disclosure are not limited thereto.

In one or more embodiments, the pixel defining layer PDL may include an inorganic material. For example, the pixel defining layer PDL may include an inorganic material such as silicon nitride (SiNₓ), silicon oxide (SiOₓ), and/or silicon oxynitride (SiOₓN_{y}).

The first to third pixel areas PXA-R, PXA-G, and PXA-B may be divided according to colors of the light generated from the first to third light emitting elements ED-R, ED-G, and ED-B. For example, in the display device DM according to one or more embodiments, the first pixel area PXA-R may correspond to a red light emitting area, the second pixel area PXA-G may correspond to a green light emitting area, and the third pixel area PXA-B may correspond to a blue light emitting area.

In the display device DM according to one or more embodiments, the light emitting elements ED-R, ED-G, and ED-B may be to emit light in different wavelength regions from one another. For example, in one or more embodiments, the first light emitting element ED-R may correspond to a red light emitting element that emits red light, the second light emitting element ED-G may correspond to a green light emitting element that emits green light, and the third light emitting element ED-B may correspond to a blue light emitting element that emits blue light.

Although FIG. 6 and/or the like illustrates the three first to third pixel areas PXA-R, PXA-G, and PXA-B separated from one another, embodiments of the present disclosure are not limited thereto, for example, the display device DM according to one or more embodiments may include four or more types (kinds) of light emitting areas having different luminescent properties.

In the display panel DP, the base layer BS may be a member which provides a base surface on which the display layer EDL and the circuit layer DP-CL are arranged. The base layer BS may be a glass substrate, a metal substrate, a plastic substrate, and/or the like. However, embodiments of the present disclosure are not limited thereto, and the base layer BS may be an inorganic layer, an organic layer, or a composite material layer.

In one or more embodiments, the circuit layer DP-CL may be arranged on the base layer BS, and the circuit layer DP-CL may include a plurality of transistors. The transistors may each include a control electrode, an input electrode, and an output electrode. For example, in one or more embodiments, the circuit layer DP-CL may include switching transistor(s) and driving transistor(s) each for driving the light emitting elements ED-R, ED-G, and ED-B of the display layer EDL.

The encapsulation layer TFE may cover the light emitting elements ED-R, ED-G, and ED-B. The encapsulation layer TFE may seal the display layer EDL. In one or more embodiments, the encapsulation layer TFE may be a thin-film encapsulation layer. In one or more embodiments, the encapsulation layer TFE may be one in which a plurality of layers is stacked.

The encapsulation layer TFE according to one or more embodiments may include at least one inorganic film (hereinafter referred to as an inorganic encapsulation film) and at least one organic film (hereinafter referred to as an organic encapsulation film). In one or more embodiments, the encapsulation layer TFE may include a first inorganic encapsulation film IOL1, an organic encapsulation film OL, and a second inorganic encapsulation film IOL2, which are stacked in sequence on the display layer EDL.

The first and second inorganic encapsulation films IOL1 and IOL2 protect the display layer EDL from moisture/oxygen, and the organic encapsulation film OL protects the display layer EDL from foreign matter such as dust particles. The first and second inorganic encapsulation films IOL1 and IOL2 may each independently include silicon nitride, silicon oxynitride, silicon oxide, titanium oxide, aluminum oxide, and/or the like, but embodiments of the present disclosure are not particularly limited thereto.

The organic encapsulation film OL may include an acryl-based compound, an epoxy-based compound, and/or the like. In one or more embodiments, the organic encapsulation film OL may include a polymer derived and polymerized from an acrylate-based monomer. The organic encapsulation film OL may include a base part BMP (see FIG. 9) including a polymer material in which the acrylate-based monomer is photopolymerized. In one or more embodiments, the organic encapsulation film OL may include an organic layer mixture including at least one of monomer compound M1 or monomer compound M2 that is the acrylate-based monomer.

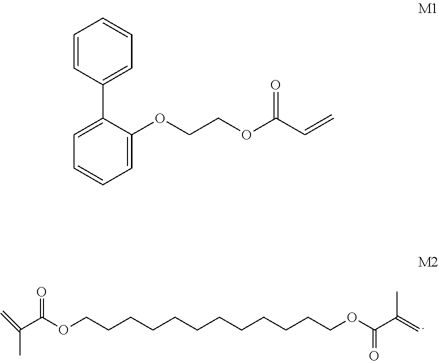

The organic layer mixture may include an organic acid additive which will be described later. The organic acid additive may have at least one carboxyl group. The organic encapsulation film OL may be obtained by ultraviolet (UV) curing the organic layer mixture including the acrylate-based monomer and the organic acid additive.

Referring to FIG. 6, in the display panel DP according to one or more embodiments, the encapsulation layer TFE may cover the light emitting elements ED-R, ED-G, and ED-B and be directly arranged on the display layer EDL. In one or more embodiments, the first inorganic encapsulation film IOL1 may be directly arranged on the display layer EDL. The organic encapsulation film OL of the encapsulation layer

TFE may be spaced and/or apart (e.g., spaced apart or separated) from the display layer EDL with the first inorganic encapsulation film IOL1 arranged between the organic encapsulation film OL and the display layer EDL. For example, in one or more embodiments, the organic encapsulation film OL may not be in direct contact with the light emitting elements ED-R, ED-G, and ED-B of the display layer EDL, and the first inorganic encapsulation film IOL1 may be in direct contact with the light emitting elements ED-R, ED-G, and ED-B and cover the light emitting elements ED-R, ED-G, and ED-B.

In one or more embodiments, the first inorganic encapsulation film IOL1 may include a material which prevents movement of monomer compounds in the organic layer mixture provided to form the organic encapsulation film OL, and allows movement of the organic acid additive. The organic acid additive may penetrate the first inorganic encapsulation film IOL1 in a fume state and be delivered to components of the light emitting elements ED below the first inorganic encapsulation film IOL1. The first inorganic encapsulation film IOL1 may include an inorganic material having properties which allow the organic acid additive to be penetrated in the fume state, and also are not modified by the monomer compounds and do not allow the monomer compounds to be penetrated.

The display device DM according to one or more embodiments may further include the optical member PP. The optical member PP may be a reflection reduction layer which reduces reflectance of external light. For example, in one or more embodiments, the optical member PP may include a polarizing film including a retarder and/or a polarizer, a plurality of reflective layers that cause reflected light to destructively interfere with each other, or color filters arranged to correspond to arrangement and emissive colors of pixels in the display panel DP. In one or more embodiments, the optical member PP may not be provided.

Referring to FIG. 6, in one or more embodiments, the optical member PP may include a base substrate BL and a color filter layer CFL.

The base substrate BL may be a member which provides a base surface on which the color filter layer CFL and/or the like are arranged. The base substrate BL may be a glass substrate, a metal substrate, a plastic substrate, and/or the like. However, embodiments of the present disclosure are not limited thereto, and the base substrate BL may be an inorganic layer, an organic layer, or a composite material layer.

In one or more embodiments, the color filter layer CFL may include first to third color filters CF-R, CF-G and CF-B. The first to third color filters CF-R, CF-G, and CF-B may be arranged to correspond to the first to third light emitting elements ED-R, ED-G, and ED-B, respectively. For example, in one or more embodiments, the first color filter CF-R may be a red filter, the second color filter CF-G may be a green filter, and the third color filter CF-B may be a blue filter. The first to third color filters CF-R, CF-G, and CF-B may be arranged to correspond to the first to third pixel areas PXA-R, PXA-G, and PXA-B, respectively.

The plurality of color filters CF-R, CF-G, and CF-B which transmit different light may be arranged to overlap each other in an area corresponding to a peripheral area NPXA arranged between the pixel areas PXA-R, PXA-G, and PXA-B. The plurality of color filters CF-R, CF-G, and CF-B may be arranged to overlap each other in the third direction DR3 that is a thickness direction, thereby defining a boundary between adjacent pixel areas of the pixel areas PXA-R, PXA-G, and PXA-B. Accordingly, an effect of blocking external light may be increased to have the same function as a black matrix. A superposed structure of the plurality of color filters CF-R, CF-G, and CF-B may have a function to prevent or reduce color mixture.

Each of the first to third color filters CF-R, CF-G, and CF-B may include a polymer photosensitive resin and a pigment and/or a dye. In one or more embodiments, the first color filter CF-R may include a red pigment and/or a red dye, the second color filter CF-G may include a green pigment and/or a green dye, and the third color filter CF-B may include a blue pigment and/or a blue dye. However, embodiments of the present disclosure are not limited thereto, for example, in one or more embodiments, the third color filter CF-B may not include (e.g., may exclude) a pigment or a dye. The third color filter CF-B may include a polymer photosensitive resin but not include a pigment or a dye. The third color filter CF-B may be transparent. The third color filter CF-B may include transparent photosensitive resin.

The color filter layer CFL may further include a buffer layer BFL. For example, the buffer layer BFL may be a protective layer which protects the first to third color filters CF-R, CF-G, and CF-B. The buffer layer BFL may be an inorganic material layer including at least one inorganic material selected from among silicon nitride, silicon oxide, and silicon oxynitride. The buffer layer BFL may have a single-layer structure or a multilayer structure.

In one or more embodiments, the first color filter CF-R and the second color filter CF-G may each be a yellow filter. The first color filter CF-R and the second color filter CF-G may not be separated from each other but be provided as one body.

In one or more embodiments, the color filter layer CFL may further include a light blocking part. The light blocking part may be a black matrix. The light blocking part may include an organic light blocking material and/or an inorganic light blocking material each including a black pigment and/or a black dye. The light blocking part may prevent or reduce light leakage, and define a boundary between adjacent color filters of the color filters CF-R, CF-G, and CF-B.

Unlike an embodiment illustrated in FIG. 6 and/or the like, the optical member PP of the display device DM according to one or more embodiments may not include (e.g., may exclude) the color filter layer CFL.

In the display panel DP according to one or more embodiments, each of the first to third light emitting elements ED-R, ED-G, and ED-B may include a first electrode AE, a hole transport region HTR, an emission layer EML-R, EML-G, or EML-B, an electron transport region ETR, and a second electrode CE. In one or more embodiments, each of the first to third light emitting elements ED-R, ED-G, and ED-B may further include a capping layer CPL arranged on the second electrode CE.

The first electrode AE may be exposed in the pixel opening portion OH of the pixel defining layer PDL. The first electrode AE has conductivity (e.g., is an electron conductor). The first electrode AE may include a metal material, a metal alloy, or a conductive compound. The first electrode AE may be an anode or a cathode. The first electrode AE may also be a pixel electrode. The first electrode AE may be a transmissive electrode, a semi-transmissive electrode, or a reflective electrode.

The second electrode CE may be arranged on the first electrode AE. The second electrode CE may be arranged to oppose the first electrode AE with the respective emission layer EML-R, EML-G, or EML-B arranged between the second electrode CE and the first electrode AE. The second electrode CE may be a cathode or an anode. In one or more embodiments, if (e.g., when) the first electrode AE is an anode, the second electrode CE may be a cathode, and if (e.g., when) the first electrode AE is a cathode, the second electrode CE may be an anode. In one or more embodiments, the second electrode CE may be a common electrode. The second electrode CE may be a transmissive electrode, a semi-transmissive electrode, or a reflective electrode.

The first electrode AE may be divided and arranged so as to correspond to each of the pixel areas PXA-R, PXA-G, and PXA-B. The second electrode CE may be provided as a common layer to the entirety of the pixel areas PXA-R, PXA-G, and PXA-B.

The hole transport region HTR may be arranged between the first electrode AE and the respective emission layers EML-R, EML-G, and EML-B, and the electron transport region ETR may be arranged between the respective emission layers EML-R, EML-G, and EML-B and the second electrode CE. Referring to FIG. 6, each of the hole transport region HTR and the electron transport region ETR may be provided as a common layer to the entirety of the pixel areas PXA-R, PXA-G, and PXA-B. However, embodiments of the present disclosure are not limited thereto, and the hole transport region HTR and the electron transport region ETR may each independently be divided and arranged so as to correspond to each of the pixel areas PXA-R, PXA-G, and PXA-B.

In one or more embodiments illustrated in FIG. 6, the respective emission layers EML-R, EML-G, and EML-B of the first to third light emitting elements ED-R, ED-G, and ED-B may be each arranged within the pixel opening portion OH. For example, in one or more embodiments, the emission layers EML-R, EML-G, and EML-B may be divided and arranged so as to correspond to the pixel areas PXA-R, PXA-G, and PXA-B, respectively. In one or more embodiments, the emission layers EML-R, EML-G, and EML-B may include quantum dots.

In one or more embodiments, each of the first to third light emitting elements ED-R, ED-G, and ED-B may include the capping layer CPL. The capping layer CPL may be arranged on the second electrode CE. The capping layer CPL may have a multilayer structure or a single-layer structure. Referring to FIG. 6, in the display panel DP according to one or more embodiments, the capping layer CPL may be provided as a common layer to the entirety of the pixel areas PXA-R, PXA-G, and PXA-B.

In each of the first to third light emitting elements ED-R, ED-G, and ED-B illustrated in FIG. 6 and/or the like, a stacked structure of the hole transport region HTR, the respective emission layer EML-R, EML-G, or EML-B, the electron transport region ETR arranged between the first electrode AE and the second electrode CE may be referred to as one emission unit. Although FIG. 6 and/or the like illustrate an embodiment in which each of the first to third light emitting elements ED-R, ED-G, and ED-B includes one emission unit, embodiments of the present disclosure are not limited thereto, for example, in one or more embodiments, the first to third light emitting elements ED-R, ED-G, and ED-B may each independently include a plurality of emission units stacked between the first electrode AE and the second electrode CE in the thickness direction. For example, the first to third light emitting elements ED-R, ED-G, and ED-B may each independently be a tandem light emitting element including a plurality of emission layers stacked in the thickness direction.

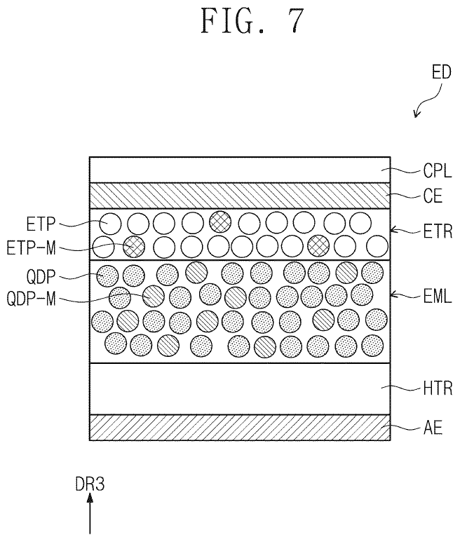

FIG. 7 is a cross-sectional view of a light emitting element according to one or more embodiments of the present disclosure. FIG. 7 illustrates an example of a structure of one of a plurality of light emitting elements included in a display panel DP according to one or more embodiments. The cross-sectional view illustrates an example of a light emitting element ED illustrated in FIG. 7, which may represent any one of the first to third light emitting elements ED-R, ED-G, and ED-B included in the display layer EDL illustrated in FIG. 6.

Referring to FIG. 7, the light emitting element ED according to one or more embodiments may include a first electrode AE, a second electrode CE opposite to (e.g., facing) the first electrode AE, and a hole transport region HTR, an emission layer EML, and an electron transport region ETR, which are arranged between the first electrode AE and the second electrode CE. The light emitting element ED may further include a capping layer CPL arranged on the second electrode CE.

The first electrode AE has conductivity (e.g., is an electron conductor). The first electrode AE may include a metal material, a metal alloy, or a conductive compound. The first electrode AE may include at least one selected from among silver (Ag), magnesium (Mg), copper (Cu), aluminum (AI), platinum (Pt), palladium (Pd), gold (Au), nickel (Ni), neodymium (Nd), iridium (Ir), chromium (Cr), lithium (Li), calcium (Ca), lithium fluoride (LiF), molybdenum (Mo), titanium (Ti), tungsten (W), indium (In), tin (Sn), and zinc (Zn), a compound of two or more selected therefrom, a mixture of two or more selected therefrom, or an oxide thereof.

In embodiments in which the first electrode AE is a transmissive electrode, the first electrode AE may include a transparent metal oxide, for example, indium tin oxide (ITO), indium zinc oxide (IZO), zinc oxide (ZnO), indium tin zinc oxide (ITZO), and/or the like. In embodiments in which the first electrode AE is a semi-transmissive electrode or a reflective electrode, the first electrode AE may include Ag, Mg, Cu, Al, Pt, Pd, Au, Ni, Nd, Ir, Cr, Li, Ca, LiF/Ca (a stacked structure of LiF and Ca), LiF/AI (a stacked structure of LiF and Al), Mo, Ti, W, or a compound or a mixture thereof (e.g., a mixture of Ag and Mg). In one or more embodiments, the first electrode AE may have a multilayer structure including a reflective film or a semi-transmissive film, each of which may include one or more of the foregoing materials, and a transparent conductive film which includes indium tin oxide (ITO), indium zinc oxide (IZO), zinc oxide (ZnO), indium tin zinc oxide (ITZO), and/or the like. For example, in one or more embodiments, the first electrode AE may have a three-layer structure of ITO/Ag/ITO, but embodiments of the present disclosure are not limited thereto.

The second electrode CE may be a transmissive electrode, a semi-transmissive electrode, or a reflective electrode. In embodiments in which the second electrode CE is a transmissive electrode, the second electrode CE may include a transparent metal oxide, for example, indium tin oxide (ITO), indium zinc oxide (IZO), zinc oxide (ZnO), indium tin zinc oxide (ITZO), and/or the like.

In embodiments in which the second electrode CE is a semi-transmissive electrode or a reflective electrode, the second electrode CE may include Ag, Mg, Cu, Al, Pt, Pd, Au, Ni, Nd, Ir, Cr, Li, Ca, LiF/Ca, LiF/AI, Mo, Ti, Yb, W, or a compound or a mixture thereof (e.g., AgMg, AgYb, or MgYb). In one or more embodiments, the second electrode CE may have a multilayer structure including a reflective film or a semi-transmissive film, each of which may include one or more of the foregoing materials, and a transparent conductive film which includes indium tin oxide (ITO), indium zinc oxide (IZO), zinc oxide (ZnO), indium tin zinc oxide (ITZO), and/or the like. For example, in one or more embodiments, the second electrode CE may include one of the foregoing metal materials, a combination of two or more metal materials selected from among the foregoing metal materials, an oxide of the foregoing metal materials, and/or the like.

In one or more embodiments, the capping layer CPL may be further arranged on the second electrode CE. The capping layer CPL may have a multilayer structure or a single-layer structure.

In one or more embodiments, the capping layer CPL may be an organic layer or an inorganic layer. For example, in embodiments in which the capping layer CPL includes an inorganic material, the inorganic material may include an alkali metal compound such as LiF, an alkaline earth metal compound such as MgF₂, SiON, SiNₓ, SiO_{y}, and/or the like.

For example, in embodiments in which the capping layer CPL includes an organic material, the organic material may include N,N′-Bis (naphthalen-1-yl)-N,N′-bis(phenyl)-2,2′-dimethylbenzidine (α-NPD), N,N′-di(naphthalene-1-yl)-N,N′-diphenyl-benzidine (NPB), N,N′-bis(3-methylphenyl)-N,N′-diphenyl-[1,1-biphenyl]-4,4′-diamine (TPD), 4,4′,4″-[tris(3-methylphenyl)phenylamino] triphenylamine (m-MTDATA), tris(8-hydroxyquinolinato)aluminum (Alq₃), copper phthalocyanine (CuPc), N4,N4,N4′, N4′-tetra (biphenyl-4-yl)biphenyl-4,4′-diamine (TPD15), 4,4′,4″-Tris (carbazol-9-yl) triphenylamine (TCTA), and/or the like, or include an epoxy resin, or an acrylate such as methacrylate. However, embodiments of the present disclosure are not limited thereto, and the capping layer CPL may include at least one of (e.g., at least one selected from among) Compounds P1 to P5 as follows.

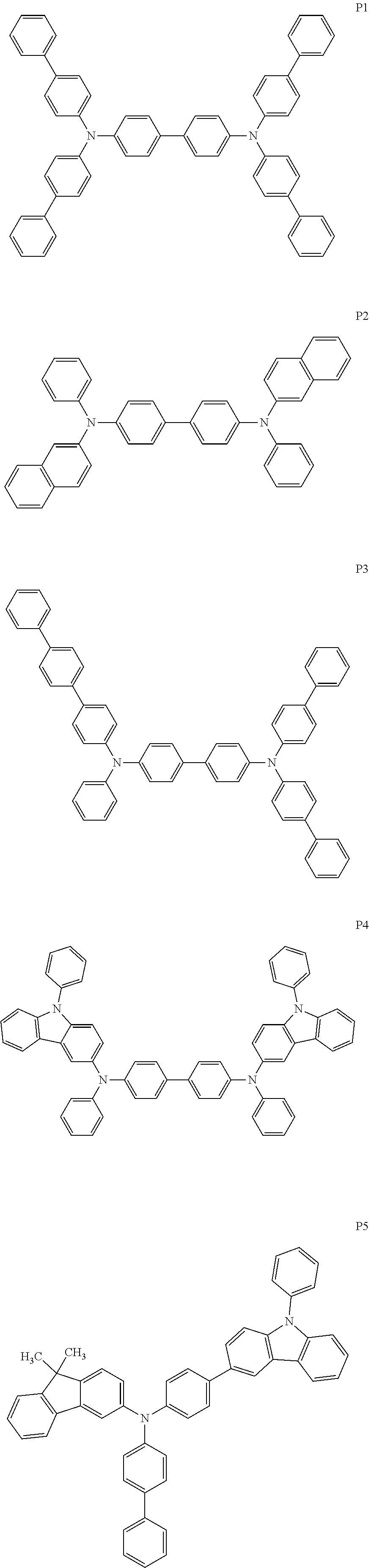 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

The capping layer CPL may have a refractive index of about 1.6 or more. For example, the refractive index of the capping layer CPL may be about 1.6 or more with respect to light having a wavelength range of about 550 nanometers (nm) to about 660 nm.

The hole transport region HTR may be arranged between the first electrode AE and the emission layer EML. The hole transport region HTR may include a general hole transport material. The hole transport region HTR may be formed using one or more suitable methods such as a vacuum deposition method, a spin coating method, a casting method, a Langmuir-Blodgett (LB) method, an inkjet printing method, a laser printing method, and/or a laser induced thermal imaging method.

The hole transport region HTR may have a single layer including a single material, a single layer including a plurality of different materials, or a multilayer structure having a plurality of layers including a plurality of different materials. The hole transport region HTR may include at least one of a hole injection layer, a hole transport layer, a buffer layer or an emission auxiliary layer, or an electron blocking layer.

In one or more embodiments, the hole transport region HTR may include one or more selected from among a phthalocyanine compound such as copper phthalocyanine, N1, N1′-([1,1′-biphenyl]-4,4′-diyl)bis(N1-phenyl-N4,N4-di-m-tolylbenzene-1,4-diamine) (DNTPD), 4,4′,4″-[tris(3-methylphenyl)phenylamino] triphenylamine (m-MTDATA), 4,4′4″-Tris (N,N-diphenylamino)triphenylamine (TDATA), 4,4′,4″-tris [N (2-naphthyl)-N-phenylamino]-triphenylamine (2-TNATA), Poly (3,4-ethylenedioxythiophene)/Poly (4-styrenesulfonate) (PEDOT/PSS), Polyaniline/Dodecylbenzenesulfonic acid (PANI/DBSA), Polyaniline/Camphor sulfonicacid (PANI/CSA), Polyaniline/Poly (4-styrenesulfonate) (PANI/PSS), N,N′-di(naphthalen-1-yl)-N,N′-diphenyl-benzidine (NPB), triphenylamine-containing polyetherketone (TPAPEK), 4-Isopropyl-4′-methyldiphenyliodonium [Tetrakis (pentafluorophenyl)borate], dipyrazino[2,3-f:2′,3′-h] quinoxaline-2,3,6,7,10,11-hexacarbonitrile (HATCN), and/or the like.

In one or more embodiments, the hole transport region HTR may include one or more selected from among carbazole-based derivatives such as N-phenyl carbazole and/or polyvinyl carbazole, fluorene-based derivatives, triphenylamine-based derivatives such as N,N′-bis(3-methylphenyl)-N,N′-diphenyl-[1,1′-biphenyl]-4,4′-diamine (TPD) and/or 4,4′,4″-tris(N-carbazolyl)triphenylamine (TCTA), N,N′-di(naphthalen-1-yl)-N,N′-diphenyl-benzidine (NPB), 4,4′-Cyclohexylidene bis[N,N-bis(4-methylphenyl)benzenamine] (TAPC), 4,4′-Bis [N,N′-(3-tolyl)amino]-3,3′-dimethylbiphenyl (HMTPD), 1,3-Bis (N-carbazolyl)benzene (mCP), and/or the like.

In one or more embodiments, the hole transport region HTR may include one or more selected from among 9-(4-tert-Butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), and/or the like.

The electron transport region ETR may be arranged between the emission layer EML and the second electrode CE. The electron transport region ETR may include a general electron transport material. The electron transport region ETR may be formed using one or more suitable methods such as a vacuum deposition method, a spin coating method, a casting method, a Langmuir-Blodgett (LB) method, an inkjet printing method, a laser printing method, and/or a laser induced thermal imaging method.

The electron transport region ETR may have a single layer including a single material, a single layer including a plurality of different materials, or a multilayer structure having a plurality of layers including a plurality of different materials. The electron transport region ETR may include an electron transport layer and an electron injection layer, which are stacked. In one or more embodiments, the electron transport region ETR may include at least one of a hole blocking layer, an electron transport layer, a buffer layer, or an electron injection layer.

In one or more embodiments, the electron transport region ETR may include a metal oxide (e.g., in a form of particles). The electron transport region ETR may include at least one of types (kinds) of metal oxides such as Li₂O, BaO, ZnO, ZnMgO, or MgO.

In one or more embodiments, the electron transport region ETR may further include one or more other general electron transport materials. For example, in one or more embodiments, the electron transport region ETR may include Tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzimidazol-1-yl)phenyl)-9,10-dinaphthylanthracene, 1,3,5-Tri (1-phenyl-1H-benzo[d] imidazol-2-yl)benzene (TPBi), 2,9-Dimethyl-4,7-diphenyl-1,10-phenanthroline (BCP), 4,7-Diphenyl-1,10-phenanthroline (Bphen), 3-(Biphenyl-4-yl)-4-phenyl-5-tert-butylphenyl-1,2,4-triazole (TAZ), 4-(Naphthalen-1-yl)-3,5-diphenyl-4H-1,2,4-triazole (NTAZ), 2-(Biphenyl-4-yl)-5-(4-tert-butylphenyl)-1,3,4-oxadiazole (tBu-PBD), Bis (2-methyl-8-quinolinolato-N1,O8)-(1,1′-Biphenyl-4-olato)aluminum (BAlq), berylliumbis(benzoquinolin-10-olate) (Bebq₂), 9,10-di(naphthalen-2-yl)anthracene (ADN), 1,3-Bis [3,5-di(pyridin-3-yl)phenyl] benzene (BmPyPhB), or a mixture thereof, and/or 8-hydroxyquinolinolato-lithium (Liq) and/or the like.

In one or more embodiments, the electron transport region ETR may include a halogenated metal (e.g., metal halide) such as LiF, NaCl, CsF, RbCl, RbI, CuI, and/or KI, a lanthanum group metal such as Yb, or a co-deposition material of the halogenated metal and the lanthanum group metal. For example, in one or more embodiments, the electron transport region ETR may include KI:Yb, RbI:Yb, LiF:Yb, and/or the like as a co-deposition material.

In one or more embodiments, the electron transport region ETR may also include a material in which an electron transport material and an insulating organo metal salt are mixed. The organo metal salt may be a material having an energy band gap of about 4 eV or more. For example, the organo metal salt may include one or more selected from among metal acetates, metal benzoates, metal acetoacetates, metal acetylacetonates, and metal stearates.

In one or more embodiments, the electron transport region ETR may further include, in addition to one or more of the foregoing materials, at least one of 2,9-dimethyl-4,7-diphenyl-1,10-phenanthroline (BCP), diphenyl (4-(triphenylsilyl)phenyl) phosphine oxide (TSPO1), or 4,7-diphenyl-1,10-phenanthroline (Bphen), but embodiments of the present disclosure are not limited thereto.

In the light emitting element ED according to one or more embodiments of the present disclosure, the electron transport region ETR may include a metal oxide particle ETP and a modified metal oxide particle ETP-M including a carboxyl derivative coupled to an outer edge of the metal oxide particle ETP. For example, in the light emitting element ED according to one or more embodiments, the electron transport region ETR may include the metal oxide particle ETP including a metal oxide such as ZnO, ZnMgO, or MgO, and the modified metal oxide particle ETP-M in which the carboxyl derivative is coupled to the metal oxide particle ETP. The modified metal oxide particle ETP-M may correspond to a state in which a defect of the metal oxide particle is passivated by introduction of the carboxyl derivative into an oxygen vacancy portion in which oxygen atoms are separated from the metal oxide particle.

During a heat treatment, the organic acid additive introduced into the light emitting element ED may be moved and coupled to the metal oxide particle in the electron transport region ETR to obtain the modified metal oxide particle ETP-M.

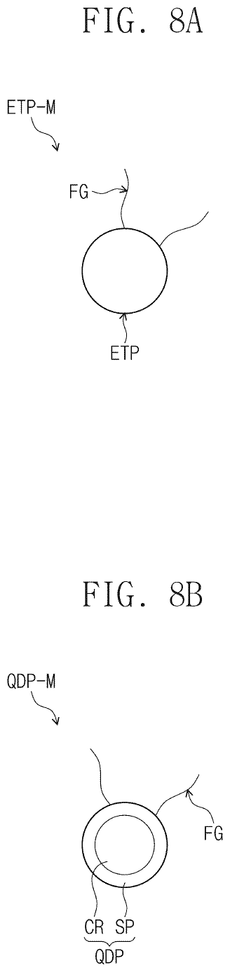

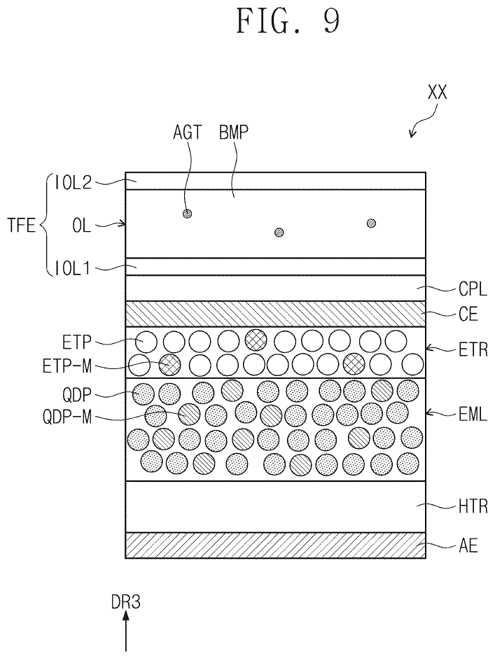

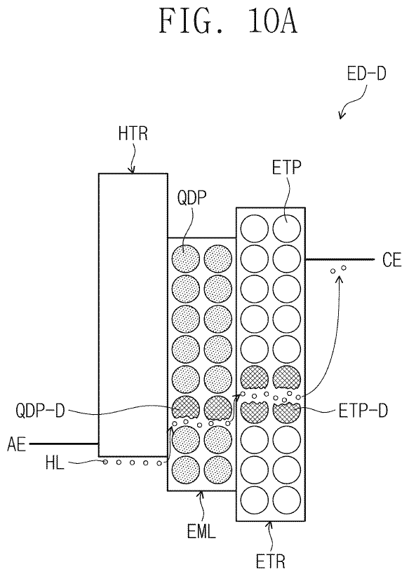

FIG. 8A is a schematic view illustrating a configuration of a modified metal oxide particle ETP-M according to one or more embodiments. Referring to FIG. 8A, the modified metal oxide particle ETP-M according to one or more embodiments may include a metal oxide particle ETP and a carboxyl derivative FG coupled to a metal oxide particle ETP. The metal oxide particle ETP constituting the modified metal oxide particle ETP-M may include an oxygen vacancy.

As the electron transport region ETR includes the modified metal oxide particle ETP-M, a vacancy defect in the metal oxide particle having an oxygen vacancy defect may be passivated by the carboxyl derivative, and thus outflow of holes through the oxygen vacancy defect may be reduced. In addition, as the electron transport region ETR includes the modified metal oxide particle ETP-M in which the carboxyl derivative derived from an organic acid additive having a carboxyl group is coupled, the light emitting element ED according to one or more embodiments may be improved in charge balance, reduced in leakage current, and improved in quenching phenomenon. Accordingly, the light emitting element ED according to one or more embodiments and the display panel including the light emitting element ED may exhibit excellent or suitable luminance efficiency and long lifespan characteristics.

The emission layer EML according to one or more embodiments may include a plurality of quantum dots QDP. In addition, the emission layer EML according to one or more embodiments may include the plurality of quantum dots QDP and at least one modified quantum dot QDP-M. The modified quantum dot QDP-M may include a carboxyl derivative coupled to an outer edge of a quantum dot.

As used here, the quantum dot QDP refers to a crystal of a semiconductor compound. The quantum dot QDP may be to emit light having one or more suitable emission wavelengths according to a size of the crystal. The quantum dot QDP may be to emit light having one or more suitable emission wavelengths by adjusting a ratio of elements in the semiconductor compound.

The quantum dot QDP may have a diameter of, for example, about 1 nm to about 10 nm. In the present disclosure, when quantum dots or quantum dot particles are spherical, “diameter” indicates a particle diameter or an average particle diameter, and when the particles are non-spherical, the “diameter” indicates a major axis length or an average major axis length. The diameter of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter is referred to as D50. D50 refers to the average diameter of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size. In the present disclosure, when particles are spherical, “diameter” indicates an average particle diameter, and when the particles are non-spherical, the “diameter” may indicate a major axis length. The quantum dot QDP may be synthesized through a wet chemical process, a metal organic chemical vapor deposition process, a molecular beam epitaxy process, or a similar process.

Among the quantum dot manufacturing processes, the wet chemical process is a method of mixing an organic solvent and a precursor material of a quantum dot and then growing quantum dot QDP particle crystals. When the quantum dot QDP particle crystals grow, the organic solvent may naturally serve as a dispersant coordinated on surfaces of the quantum dot crystals, and control the growth of the particle crystals. Thus, in the wet chemical process, the growth of quantum dot particles may be controlled or selected through a process performed more easily and at lower costs than a vapor deposition process such as metal organic chemical vapor deposition or molecular beam epitaxy.

In one or more embodiments, the quantum dot QDP may include a core CR and a shell SP (see FIG. 8B). The core CR of the quantum dot QDP may be selected from among a Group II-VI compound, a Group III-V compound, a Group III-VI compound, a Group I-III-VI compound, a Group IV-VI compound, a Group II-IV-V compound, a Group IV element, a Group IV compound, and a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof. In one or more embodiments, the Group II-VI semiconductor compound may further include a Group I metal and/or a Group IV element. The Group I-II-VI compound may be selected from among CuSnS and CuZnS, and the Group II-IV-VI compound may be selected from among ZnSnS and/or the like. The Group I-II-IV-VI compound may be selected from among quaternary compounds selected from the group consisting of Cu₂ZnSnS₂, Cu₂ZnSnS₄, Cu₂ZnSnSe₄, Ag₂ZnSnS₂, and a mixture thereof.

The Group III-VI compound may include a binary compound such as In₂S₃ and/or In₂Se₃, a ternary compound such as InGaS₃ and/or InGaSe₃, or any combination thereof.

The Group I-III-VI compound may be selected from among a ternary compound selected from the group consisting of AgInS, AgInS₂, CuInS, CuInS₂, AgGaS₂, CuGaS₂, CuGaO₂, AgGaO₂, AgAlO₂, and a mixture thereof, and a quaternary compound such as AgInGaS₂ and/or CuInGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. In one or more embodiments, the Group III-V compound may further include a Group II metal. For example, the Group III-II-V compound may be selected from among InZnP and/or the like.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof.

Non-limiting examples of the Group II-IV-V compound may include a ternary compound selected from the group consisting of ZnSnP, ZnSnP₂, ZnSnAs₂, ZnGeP₂, ZnGeAs₂, CdSnP₂, and CdGeP₂, and a mixture thereof.

The Group IV element may be selected from the group consisting of Si, Ge, and a mixture thereof. The Group IV compound may be a binary compound selected from the group consisting of SiC, SiGe, and a mixture thereof.

Each of elements included in a multi-element compound such as a binary compound, a ternary compound, or a quaternary compound, may be present in a particle at a substantially uniform concentration or non-uniform concentration. For example, the representation of a chemical formula representing the quantum dot QDP indicates types (kinds) of elements included in a quantum dot compound, and ratios of the elements in the compound may vary.

In one or more embodiments, the binary compound, the ternary compound, or the quaternary compound may be present at a substantially uniform concentration in a particle, or may be divided in partially different concentration distributions and present in a same particle. In addition, the quantum dot may have a core/shell structure (see FIG. 8B) in which one quantum dot surrounds another quantum dot. In the core/shell structure, the quantum dot may have a concentration gradient in which the concentration of an element present in the shell gradually decreases toward the core.

The shell (e.g., shell SP) of the quantum dot QDP may serve as a protective layer for preventing or reducing a chemical change of the core to maintain semiconductor characteristics, and/or as a charging layer for imparting electrophoretic characteristics to the quantum dot QDP. The shell may have a single-layer structure or a multilayer structure. Examples of the shell of the quantum dot may include a metal or nonmetal oxide, a semiconductor compound, or a combination thereof.

For example, the metal or nonmetal oxide suitable for the shell may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, or a ternary compound such as MgAl₂O₄, CoFe₂O₄, NiFe₂O₄, and/or CoMn₂O₄, but embodiments of the present disclosure are not limited thereto.

In addition, examples of the semiconductor compound suitable for the shell may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like, but embodiments of the present disclosure are not limited thereto.

For example, in one or more embodiments, if (e.g., when) the quantum dot of the Group III-V compound has a core-shell structure, the quantum dot may include InP or InZnP as the core and include ZnSeS as the shell, or have a dual shell structure of ZnSe/ZnS. However, embodiments of the present disclosure are not limited thereto, for example, the quantum dot may have a combination of the core and the shell, selected from among the foregoing semiconductor compounds.

The quantum dot QDP may have a full width of half maximum (FWHM) of an emission spectrum of about 45 nm or less, about 40 nm or less, or about 30 nm or less, and, in this range, color purity or color reproducibility of the quantum dot may be improved. Moreover, light emitted through the quantum dot may be emitted in all directions, and thus a wide viewing angle may be improved.

In addition, the form of the quantum dot QDP is a form generally used in the relevant field, and is not particularly limited. For example, a quantum dot in the form of spherical nanoparticles, pyramidal nanoparticles, multi-armed nanoparticles, or cubic nanoparticles, or in the form of nanotubes, nanowires, nanofibers, or nanoplate, and/or the like, may be used.

In the quantum dot QDP, an energy band gap may be adjusted by adjusting the size of the quantum dot or adjusting the ratio of elements in a quantum dot compound, and thus light having one or more suitable wavelength bands may be obtained from the emission layer EML including the quantum dot QDP. In one or more embodiments, the quantum dots (having different sizes and/or having different ratios of elements in the quantum dot compound) as described above may be used to achieve a light emitting element that emits light having several wavelengths. For example, the size of the quantum dot or the ratio of elements in the quantum dot compound may be selectively adjusted so as to enable the quantum dots to emit red, green, and/or blue light. In one or more embodiments, the quantum dots QDP may be configured so as to emit white light by combining light of one or more suitable colors.

In one or more embodiments, as the particle size of the quantum dot QDP is decreased, the quantum dot QDP may be to emit light in a shorter-wavelength range. For example, in quantum dots having a core having a same semiconductor compound, a particle size of the quantum dot QDP which emits green light may be less than a particle size of the quantum dot which emits red light. In addition, in the quantum dots QDP having a core having a same semiconductor compound, a particle size of the quantum dot which emits blue light may be less than the particle size of the quantum dot which emits the green light. However, embodiments of the present disclosure are not limited thereto, for example, even in the quantum dots having a same core, the particle sizes thereof may be adjusted according to a material constituting the shell, a shell thickness, and/or the like. In embodiments in which the quantum dots QDP have one or more suitable emissive colors such as blue, red, and green colors, the quantum dots QDP having different emissive colors may be different from each other in terms of the core materials.

During a heat treatment, the organic acid additive introduced into the light emitting element ED may be moved and coupled to the quantum dot in the emission layer EML to obtain the modified quantum dot QDP-M.

FIG. 8B is a schematic view illustrating a configuration of a modified quantum dot QDP-M according to one or more embodiments. Referring to FIG. 8B, the modified quantum dot QDP-M according to one or more embodiments may include a quantum dot QDP and a carboxyl derivative FG coupled to the quantum dot QDP. The quantum dot QDP constituting the modified quantum dot QDP-M may include an oxygen vacancy portion.

In one or more embodiments, the quantum dot QDP may include a core CR and a shell SP, and the carboxyl derivative FG in the modified quantum dot QDP-M may be coupled to the shell SP. The shell SP of the modified quantum dot QDP-M may include a metal oxide. An oxygen vacancy defect formed in the shell SP may be passivated by the carboxyl derivative, and thus outflow of holes through an oxygen vacancy defect may be reduced. In addition, as the modified quantum dot QDP-M, in which the carboxyl derivative derived from an organic acid additive having a carboxyl group is coupled, is included, the light emitting element ED according to one or more embodiments may be improved in charge balance, reduced in leakage current, and improved in quenching phenomenon, thereby exhibiting excellent or suitable luminance efficiency and long lifespan characteristics. Accordingly, the light emitting element ED according to one or more embodiments and the display panel including the light emitting element ED may exhibit excellent or suitable luminance efficiency and long lifespan characteristics.

FIG. 7 illustrates the light emitting element ED according to one or more embodiments in which the electron transport region ETR and the emission layer EML respectively include modified materials ETP-M and QDP-M each having the coupled carboxyl derivative. However, embodiments of the present disclosure are not limited thereto. In the light emitting element ED according to one or more embodiments, the carboxyl derivative may be coupled to only at least a portion of the quantum dots of the emission layer EML or at least a portion of the metal oxide particles of the electron transport region ETR. For example, in the light emitting element ED according to one or more embodiments, the electron transport region ETR may include the metal oxide particle ETP and the modified metal oxide particle ETP-M, and the emission layer EML may not include (e.g., may exclude) the modified quantum dot but include only the quantum dot QDP to which the carboxyl derivative is not coupled. In one or more embodiments, in the light emitting element ED, the emission layer EML may include the quantum dot QDP and the modified quantum dot QDP-M, and the electron transport region ETR may not include (e.g., may exclude) the modified metal oxide particle but include only the metal oxide particle ETP to which the carboxyl derivative is not coupled.

The carboxyl derivative included in each of the modified metal oxide particle ETP-M and the modified quantum dot QDP-M may be derived from an organic acid additive having at least one carboxyl group. In one or more embodiments, the organic acid additive may function as an aging agent which passivates an oxygen vacancy.

In one or more embodiments, the organic acid additive is introduced during forming an organic encapsulation film OL of an encapsulation layer TFE and is present as included in the organic encapsulation film OL in an initial state in manufacture of the display panel, and according to progression of aging, the organic acid additive is moved in a fume state toward the light emitting element ED. The organic acid additive may be provided to be included in the organic encapsulation film OL in the form of a thin film, and thus the organic acid additive may be prevented or reduced from being excessively (or substantially) provided to the light emitting element ED or from being in contact with the light emitting element ED, compared to a case in which the organic acid additive is directly provided to the light emitting element ED. Accordingly, a damage to each constituent layer of the light emitting element ED due to an excessive acid treatment, generation of a byproduct due to a chemical reaction of the organic acid additive with materials constituting the light emitting element ED, and/or the like may be reduced.

In addition, only an amount of the organic acid additive to have sufficient aging effect may be included in the organic encapsulation film OL, thereby preventing or reducing occurrence of a negative aging phenomenon due to the excessive acid treatment.

Thus, in the display panel DP according to one or more embodiments, the organic acid additive may be introduced during the forming of the organic encapsulation film OL, and only the limited amount of the organic acid additive included in the organic encapsulation film OL may be moved toward the light emitting element ED and be used as an aging agent for improving performance of the light emitting element ED. Accordingly, a damage to and a decrease in performance of the light emitting element ED due to excessive aging may be mitigated.

In one or more embodiments, the organic acid additive is provided as included in a thin film that is the organic encapsulation film OL, and accordingly, the organic acid additive has a characteristic in which compatibility with a monomer compound constituting the organic encapsulation film OL is excellent or suitable. In one or more embodiments, a difference (Ra) in Hansen solubility parameter between the organic acid additive and monomer compounds used for the manufacture of the organic encapsulation film OL may be less than about 12. The difference (Ra) in Hansen solubility parameter may be calculated using Equation 1.

$${( Ra )}^{2} = 4 {( {δ}_{d 2} - {δ}_{d 1} )}^{2} + {( {δ}_{p 2} - {δ}_{p 1} )}^{2} + {( {δ}_{h 2} - {δ}_{h 1} )}^{2} \qquad Equation 1$$

(δ_{d2}−δ_{d1}) is a difference in dispersion force between two materials, (δₚ₂−δₚ₁) is a difference in dipole force between the two materials, and (δₕ₂−δₕ₁) is a difference in hydrogen-bonding force between the two materials.

In one or more embodiments, the organic acid additive may have the difference (Ra) of less than about 12 in Hansen solubility parameter from each of the monomer compounds used for the manufacture of the organic encapsulation film OL and also from a mixture of monomer compounds to be used. As the organic acid additive exhibits the characteristic of the small difference (Ra) of less than about 12 in Hansen solubility parameter from each of the monomer compounds used for the manufacture of the organic encapsulation film OL, the organic acid additive may be included as easily dissolved in the monomer compounds.

In one or more embodiments, the organic acid additive may have a solubility of about 5 wt % or more with respect to an acrylate-based monomer that is a monomer compound constituting the organic encapsulation film OL. As the organic acid additive has the excellent or suitable solubility with respect to the acrylate-based monomer constituting the organic encapsulation film OL, a sufficient amount of the organic acid additive necessary for an aging treatment for improvement in performance of the light emitting element may be included in the thin film during the forming of the organic encapsulation film OL.

The organic acid additive used in one or more embodiments may have a volatile onset temperature of lower than about 90° C. and be thus easily moved toward the light emitting element ED. As the organic acid additive used in one or more embodiments has the characteristic in which volatilization is initiated at a relatively low temperature of lower than about 90° C., the organic acid additive may be easily moved toward the light emitting element ED even at a temperature which does not cause thermal damages to the light emitting element ED and the other components of the display panel DP. As used herein, the term “volatile onset temperature” may refer to a temperature at which an organic acid additive transitions from a liquid or solid state into a gaseous or fume/vapor state. It is the temperature at which the organic acid additive's vapor pressure equals its surrounding environmental pressure, causing it to evaporate or vaporize.

In addition, in one or more embodiments, the organic acid additive may have an acid dissociation constant (pKa) of about 4.8 or higher so as to minimize or reduce damages to the light emitting element ED and adjacent layers. As the organic acid additive has the relatively high acid dissociation constant, the organic acid additive may exhibit a sufficient aging effect as an acid additive within a range in which peripheral display panel components are not damaged.

In one or more embodiments, the organic acid additive may include at least one selected from among A1 to A12.

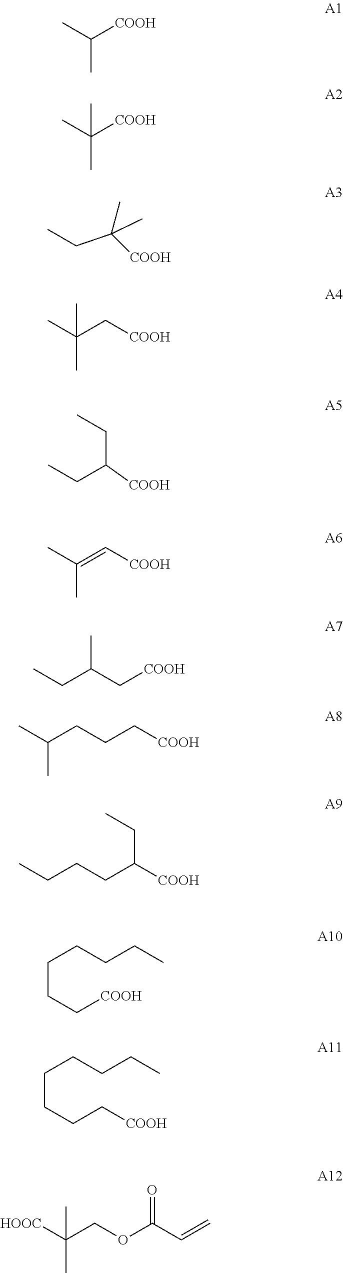

The carboxyl derivative may be derived from an organic acid additive represented by any one selected from among A1 to A12 above.

Table 1 shows characteristic values of A1 to A12 used as an organic acid additive according to one or more embodiments, and C1 that is an organic acid additive according to a comparative example. A structure of C1 that is the organic acid additive according to the comparative example is as follows.

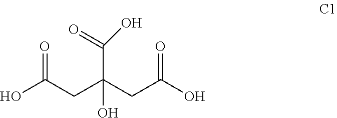 [SMILES: O=C(O)CC(O)(CC(=O)O)C(=O)O]

In Table 1, Ra (M1) corresponds to a difference in Hansen solubility parameter from the monomer compound M1 described above, and Ra (M2) corresponds to a difference in Hansen solubility parameter from the monomer compound M2 described above. In addition, in solubilities in Table 1, a solubility of the organic acid additive with respect to each of monomer compounds is expressed in weight percent (wt %). The solubility corresponds to a weight of an organic acid compound dissolved in a monomer compound with respect to 100 wt % of the monomer compound.

TABLE 1

| | | | | | Solu- | Volatile Onset |
|---|---|---|---|---|---|---|
| Cate- | CAS | | | | bility | Temperature |
| gory | No. | pKa | Ra(M1) | Ra(M2) | (wt %) | (° C.) |
| A1 | 79-31-2 | 4.8 | 9.2 | 8.6 | >30 | <<60 |
| A2 | 75-98-9 | 5.0 | 9.7 | 9.5 | >30 | <<60 |
| A3 | 595-37-9 | 5.0 | 8.5 | 8.2 | >30 | <<60 |
| A4 | 1070-83-3 | | 8.6 | 8.3 | >30 | <<60 |
| A5 | 88-09-5 | | 8.5 | 8.8 | >30 | <<60 |
| A6 | 541-47-9 | 5.1 | 9.6 | 11.3 | 10 | <<60 |
| A7 | 105-43-1 | 4.8 | 8.3 | 8.7 | >30 | <<60 |
| A8 | 628-46-6 | | 7.4 | 7.2 | >30 | 60 |
| A9 | 149-57-5 | | 7.2 | 7.2 | >30 | <<60 |
| A10 | 124-07-2 | 4.9 | 7.2 | 7.7 | >30 | 60 |
| A11 | 112-05-0 | 5.0 | 6.4 | 6.5 | >30 | 70 |
| A12 | 113824-78-5 | | 7.5 | 8.4 | 5 | 75 |
| C1 | 77-92-9 | 3.4 | 22.7 | 24.9 | <0.5 | >100 |

Referring to results in Table 1, compared to the organic acid of C1 according to the comparative example, the organic acid additives used in one or more embodiments each showed small differences in Hansen solubility parameter from the monomer compounds. The organic acid additives A1 to A12 each showed a difference of less than about 12 in Hansen solubility parameter from each of two different types (kinds) of acrylate-based monomers. This range of the Hansen solubility parameters is low compared to when C1 according to the comparative example showed a difference of about 20 or more in Hansen solubility parameter from each of the same types (kinds) of acrylate-based monomers as those used in evaluations for the organic acid additives according to one or more embodiments. Thus, it can be confirmed that compared to C1 according to the comparative example, the organic acid additives A1 to A12 used in one or more embodiments each have excellent or suitable compatibility with the acrylate-based monomers used for manufacture of an organic encapsulation film. Referring to Table 1, the organic acid additives used in one or more embodiments each exhibited higher solubility characteristics with respect to acrylate-based monomer compounds. The organic acid additives A1 to A12 each exhibited the solubility characteristic of about 5 wt % or more with respect to the monomer compounds, and this corresponds to a higher solubility characteristic compared to the case in which the organic acid additive C1 has the solubility characteristic of less than about 0.5 wt % with respect to the monomer compounds.

In addition, the organic acid additives used in one or more embodiments each exhibited a lower volatile onset temperature characteristic than the organic acid additive C1 according to the comparative example. The organic acid additives A1 to A12 were each volatilized at a temperature of lower than about 90° C., and this corresponds to a relatively low temperature compared to the case in which the organic acid additive C1 according to the comparative example was volatilized at a temperature of higher than about 100° C.

When acid dissociation constant (pKa) values shown in Table 1 are compared, A1 to A3, A6, A7, A10, and A11 had higher acid dissociation constant values compared to the organic acid additive C1 according to the comparative example. Accordingly, it may be established that the organic acid additives used in one or more embodiments each has a relatively lower acidity than the organic acid additive C1 according to the comparative example.

Referring to the results in Table 1, it may be confirmed that compared to the comparative example, the organic acid additives according to one or more embodiments each have the higher solubility with respect to the acrylate-based monomer compounds, the lower volatile onset temperature characteristics, and the relatively higher acid dissociation constant values. Accordingly, in the manufacture of the organic encapsulation film, the organic acid additive according to one or more embodiments may be provided as mixed with a monomer material for forming the organic encapsulation film, and may be included in the organic encapsulation film and then volatilized under a lower heat treatment condition to be transferred to a light emitting element, thereby exhibiting excellent or suitable aging effect.

FIG. 9 is a cross-sectional view illustrating a portion of a display panel according to one or more embodiments of the present disclosure. FIG. 9 may be a cross-sectional view illustrating the area XX in FIG. 6 according to one or more embodiments. Referring to FIG. 9, in a display panel DP according to one or more embodiments, an electron transport region ETR and an emission layer EML of a light emitting element ED may respectively include modified materials ETP-M and QDP-M in which carboxyl derivatives are coupled.

In addition, in one or more embodiments, an organic encapsulation film OL of an encapsulation layer TFE may further include an organic acid additive AGT. In one or more embodiments illustrated in FIG. 9, the organic acid additive AGT in the organic encapsulation film OL may be one which is not moved to the electron transport region ETR or the emission layer EML but remains. In one or more embodiments illustrated in FIG. 9, the emission layer EML may include a modified quantum dot QDP-M to which a carboxyl derivative derived from the organic acid additive AGT is coupled, and the electron transport region ETR may include a modified metal oxide particle ETP-M to which the carboxyl derivative derived from the organic acid additive AGT is coupled.

As described with reference to FIG. 7 and/or the like, the organic acid additive AGT may be cured as provided together with an acrylate-based monomer for forming the organic encapsulation film OL, and then be provided as included in a thin film of the organic encapsulation film OL. The organic acid additive AGT may have at least one carboxyl group and have a high solubility characteristic with respect to an acrylate-based monomer as described above. In addition, the organic acid additive AGT may have an acid dissociation constant (pKa) of about 4.8 or higher and a volatile onset temperature characteristic of lower than about 90° C. The organic acid additive AGT may include at least one selected from among A1 to A12 described above.

Only a limited amount of the organic acid additive AGT is provided to be included in the organic encapsulation film OL, and accordingly, the organic acid additive AGT remaining in the organic encapsulation film OL after aging does not cause a negative aging reaction which decreases the performance of the light emitting element.

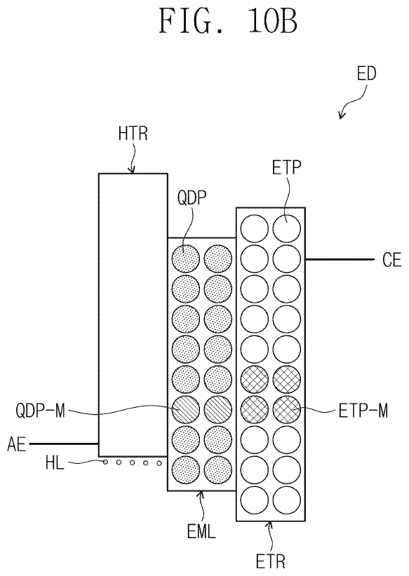

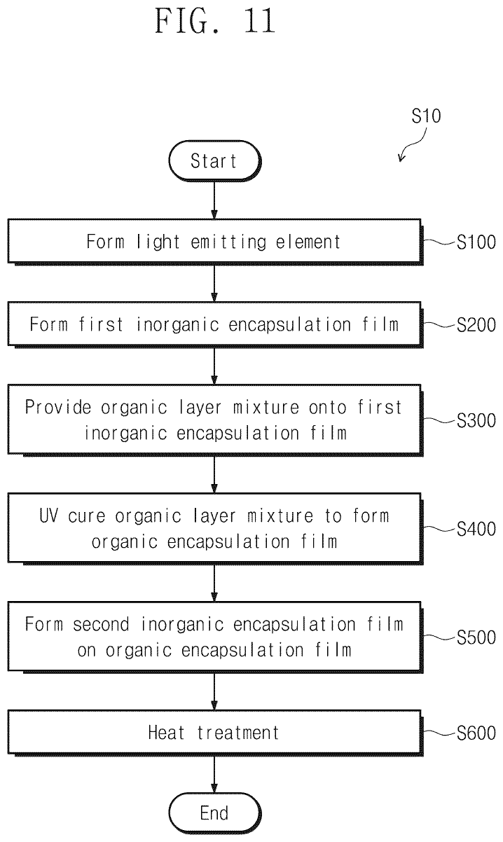

FIG. 10A and FIG. 10B are each a schematic view illustrating a hole movement characteristic in a light emitting element as an example. FIG. 10A illustrates an example of movement of a hole HL in a typical light emitting element ED-D in which an organic acid additive is not provided, and FIG. 10B illustrates an example of movement of a hole HL in a light emitting element ED according to one or more embodiments in which the organic acid additive is provided as included in an organic encapsulation film.

In the typical light emitting element ED-D in FIG. 10A, an emission layer EML may include a quantum dot QDP and a defective quantum dot QDP-D having an oxygen vacancy defect, and an electron transport region ETR may include a metal oxide particle ETP and a defective metal oxide particle ETP-D having an oxygen vacancy defect. Accordingly, the hole HL supplied from a hole transport region HTR may leak from a defective portion that is a portion of each of the defective quantum dot QDP-D and the defective metal oxide particle ETP-D. Accordingly, a charge balance may become low and a quenching phenomenon may occur to decrease efficiency and lifespan of the light emitting element ED-D.

In contrast, In the light emitting element ED according to one or more embodiments illustrated as an example in FIG. 10B, an emission layer EML may include a quantum dot QDP and a modified quantum dot QDP-M in which an oxygen vacancy defect is passivated by a carboxyl derivative, and an electron transport region ETR may include a metal oxide particle ETP and a modified metal oxide particle ETP-M in which the oxygen vacancy defect is passivated by the carboxyl derivative. For example, in the light emitting element ED according to one or more embodiments, defective portions in the emission layer EML and the electron transport region ETR may be passivated, and accordingly, leakage of the hole HL, supplied from a hole transport region HTR, up to the electron transport region ETR via the emission layer EML may be mitigated. As the emission layer EML and the electron transport region ETR each include a material which is aged with the organic acid additive and in which the oxygen vacancy defect is passivated, the light emitting element ED according to one or more embodiments may have an excellent or suitable charge balance and be reduced in element deterioration, thereby exhibiting excellent or suitable luminance efficiency and long lifespan characteristics.

A display panel according to one or more embodiments may include a light emitting element in which an emission layer includes a quantum dot, and an encapsulation layer including an organic encapsulation film to be arranged on the light emitting element, and, in the light emitting element, at least one of the emission layer or an electron transport region may include a material in which a defect is passivated by an organic acid additive provided from the organic encapsulation film, thereby exhibiting excellent or suitable efficiency and lifespan characteristics. In addition, in the display panel according to one or more embodiments, the organic acid additive may be provided in a state of being included in a thin film that is the organic encapsulation film, thereby minimizing or reducing a damage to the light emitting element caused by the organic acid additive compared to if (e.g., when) the organic acid additive is directly provided to the light emitting element. Moreover, only a limited amount of the organic acid additive may be included in the organic encapsulation film to prevent or reduce the organic acid additive from being excessively (or substantially) provided, and thus a chemical reaction of the organic acid additive with other components of the display panel may be minimized or reduced. Accordingly, the display panel according to one or more embodiments may exhibit excellent or suitable reliability characteristics.

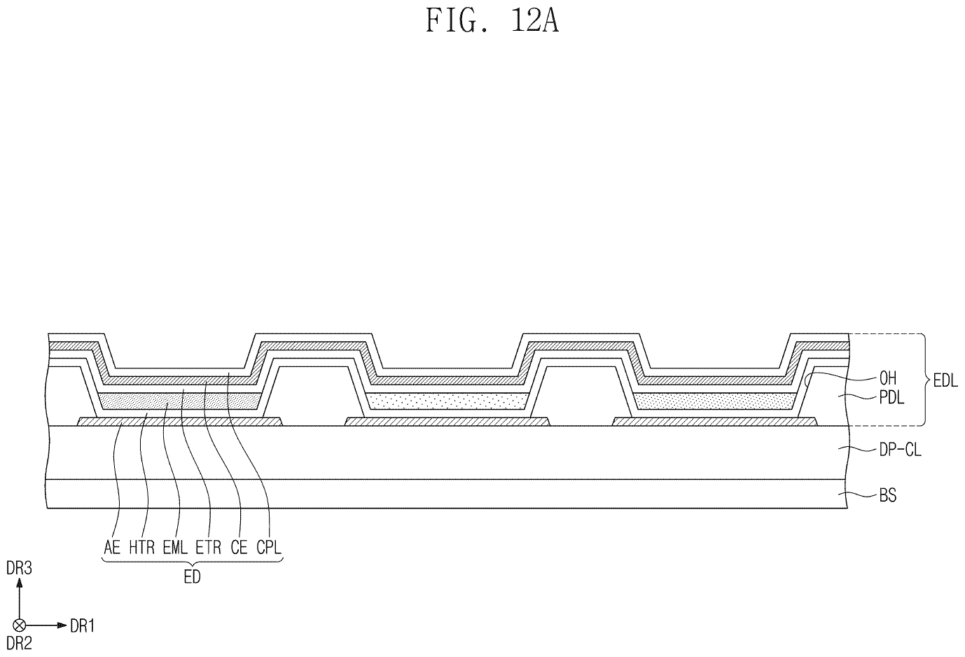

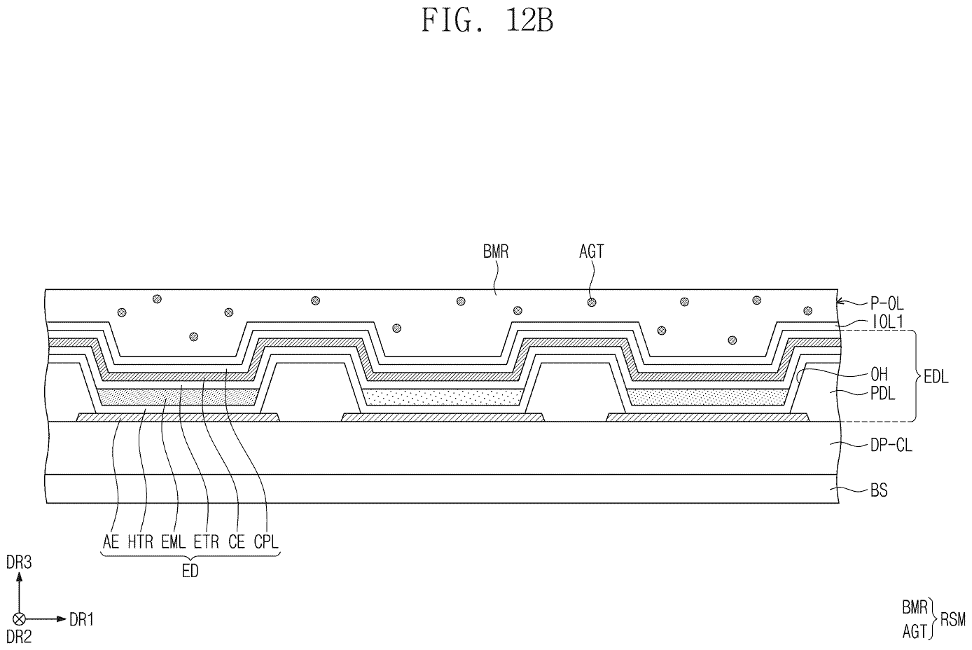

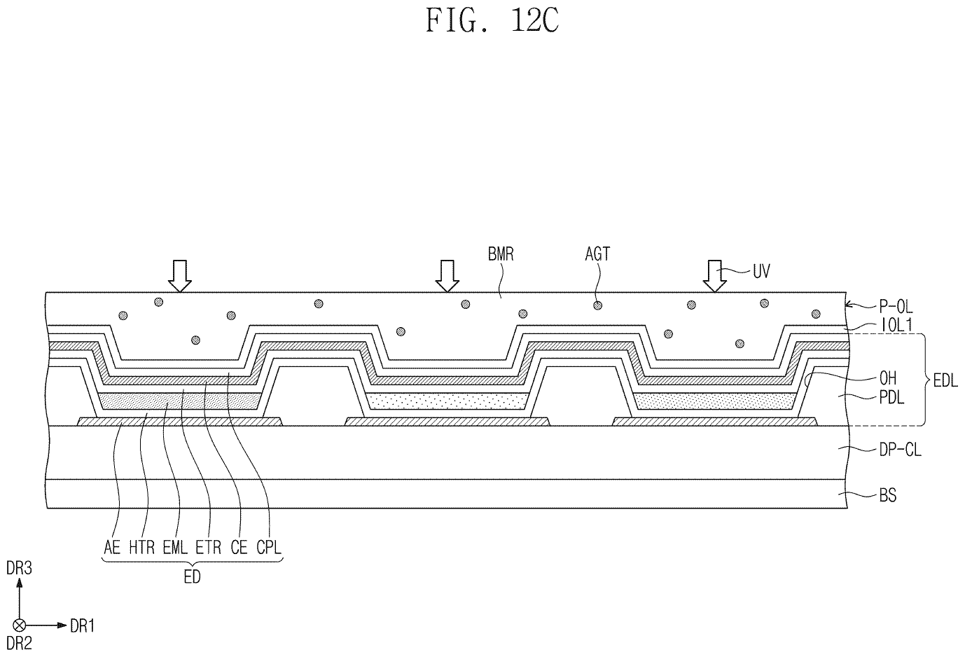

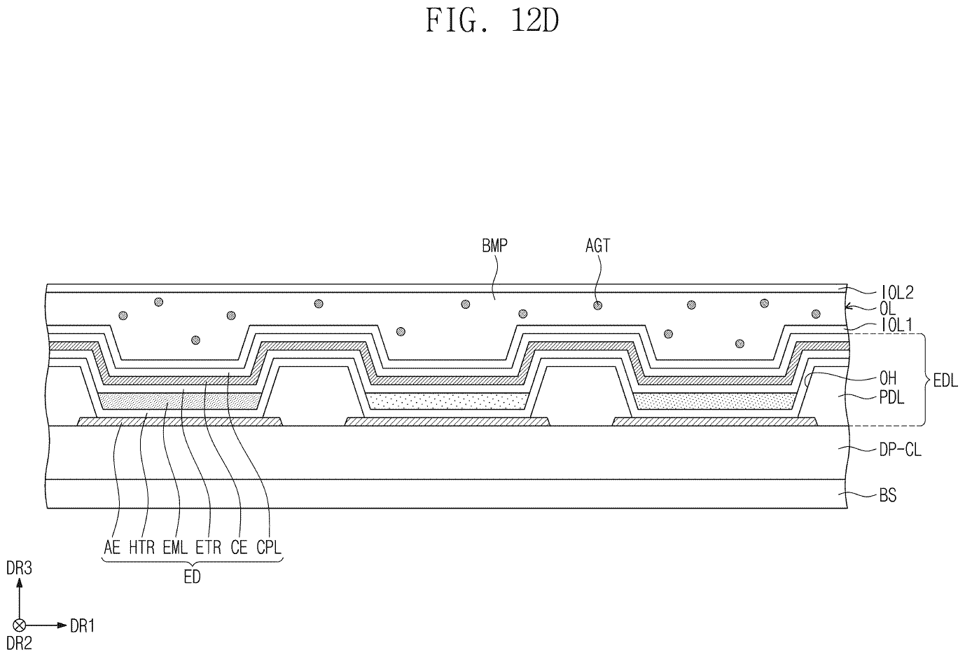

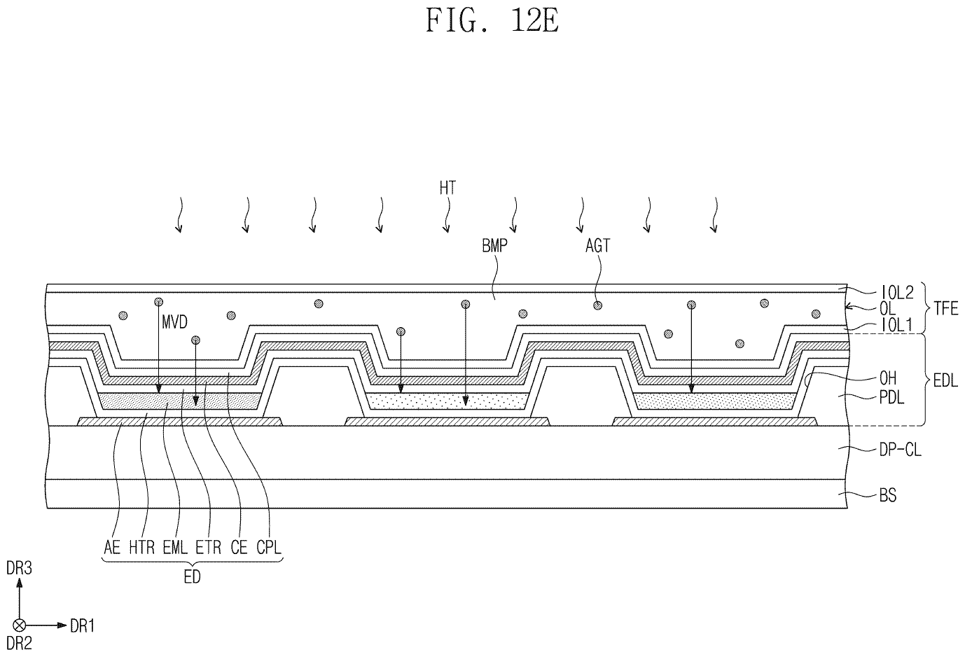

Hereinafter, a method for manufacturing a display panel according to one or more embodiments will be described with reference to FIGS. 11 and 12A to 12E. The method for manufacturing the display panel according to one or more embodiments will be described by avoiding (not repeating) the content in common with the content about the display panel according to one or more embodiments described with reference to FIGS. 1 to 9, and mainly in terms of differences.

FIG. 11 is a flowchart illustrating a method for manufacturing a display panel according to one or more embodiments of the present disclosure. FIGS. 12A to 12E are each a view illustrating an example of a step (e.g., act or task) of a method for manufacturing a display panel according to one or more embodiments.

The method for manufacturing the display panel according to one or more embodiments (S10) may include steps of forming a light emitting element (S100), forming a first inorganic encapsulation film (S200), providing (e.g., applying) an organic layer mixture onto the first inorganic encapsulation film (S300), ultraviolet (UV) curing the organic layer mixture to form an organic encapsulation film (S400), forming a second inorganic encapsulation film on the organic encapsulation film (S500), and performing a heat treatment (S600).

FIG. 12A illustrates the forming of the light emitting element (S100) as an example. In the forming of the light emitting element (S100), a first electrode AE, a hole transport region HTR, an emission layer EML, an electron transport region ETR, and a second electrode CE may be provided in sequence to form a light emitting element ED.

In the method for manufacturing the display panel according to one or more embodiments, a circuit layer DP-CL may be provided on a base layer BS, and the light emitting element ED may be formed on the circuit layer DP-CL. The first electrode AE may be formed on the circuit layer DP-CL through patterning, and then a pixel defining layer PDL in which a pixel opening portion OH is defined may be formed. The hole transport region HTR may be provided on the first electrode AE while covering the inside of the pixel opening portion OH and the pixel defining layer PDL. Thereafter, the emission layer EML may be formed on the hole transport region HTR so as to correspond to the pixel opening portion OH. The emission layer EML may include a quantum dot. The electron transport region ETR and the second electrode CE may be provided in sequence onto the emission layer EML. The electron transport region ETR and the second electrode CE may each be provided as a common layer so as to overlap the pixel opening portion OH and the pixel defining layer PDL. The electron transport region ETR may include a metal oxide particle. In addition, in one or more embodiments, the light emitting element ED may further include a capping layer CPL, and the capping layer CPL may be provided as a common layer onto the second electrode CE.

The emission layer EML may include a plurality of quantum dots, each of which includes a core and a shell around (e.g., surrounding) the core, and the electron transport region ETR may include a plurality of metal oxide particles. In the forming of the light emitting element (S100), at least a portion of the quantum dots of the emission layer EML and at least a portion of the metal oxide particles of the electron transport region ETR may have an oxygen vacancy defect.

Unlike one or more embodiments illustrated in FIG. 12A and/or the like, in one or more embodiments, each of the hole transport region HTR and the electron transport region ETR may be provided not as a common layer, but as patterned to be divided by the pixel defining layer PDL and arranged inside the pixel opening portion OH.

FIG. 12B illustrates the providing of the organic layer mixture onto the first inorganic encapsulation film (S300) as an example. The providing of an organic layer mixture RSM may be performed after the forming of the first inorganic encapsulation film (S200).

A first inorganic encapsulation film IOL1 may be arranged on a display layer EDL. The first inorganic encapsulation film IOL1 may be directly arranged on the display layer EDL while covering the light emitting element ED.

The organic layer mixture RSM may be provided and applied onto the first inorganic encapsulation film IOL1 to form a preliminary organic layer P-OL. The preliminary organic layer P-OL refers to a layer in a state before the organic layer mixture RSM is cured into an organic encapsulation film OL in the form of a thin film. The organic layer mixture RSM may include an organic acid additive AGT and an acrylate-based monomer BMR.

The first inorganic encapsulation film IOL1 may include an inorganic material which prevents the acrylate-based monomer BMR from being transferred to the display layer EDL below the first inorganic encapsulation film IOL1, and allows the organic acid additive AGT to easily move. The first inorganic encapsulation film IOL1 may not be oxidized by the organic acid additive AGT, but cover and protect the light emitting element ED.

The organic acid additive AGT may be included in an amount of about 5 wt % to about 30 wt % on the basis of a weight of the acrylate-based monomer BMR. For example, the organic acid additive AGT may be included in an amount of about 5 wt % to about 30 wt % of the weight of the acrylate-based monomer BMR. As about 5 wt % or more of the organic acid additive AGT is included, an aging effect such as passivation of an oxygen vacancy defect in the light emitting element ED may be sufficiently exhibited by the organic acid additive AGT. In addition, about 30 wt % or less of the organic acid additive AGT may be included to minimize or reduce damages to the light emitting element ED and the other components of the display panel caused by the excessive organic acid additive AGT and to prevent or reduce negative aging such as a decrease in element performance.

As described above, the organic acid additive AGT may have a high solubility characteristic with respect to the acrylate-based monomer BMR. A difference (Ra) in Hansen solubility parameter between the organic acid additive AGT and the acrylate-based monomer BMR may be less than about 12, and the solubility of the organic acid additive AGT with respect to the acrylate-based monomer BMR may be about 5 wt % or more.

In addition, the organic acid additive AGT may have an acidity that is an acid dissociation constant (pKa) of about 4.8 or higher, and thus when the organic acid additive AGT is provided as the organic layer mixture RSM, damages to other components of the light emitting element ED in addition to the first inorganic encapsulation film IOL1 and a second inorganic encapsulation film IOL2 may be minimized or reduced.

FIG. 12C is a view illustrating the UV curing of the organic layer mixture to form the organic encapsulation film (S400) as an example. FIG. 12D is a view illustrating the forming of the second inorganic encapsulation film on the organic encapsulation film (S500) as an example.

In the forming of the organic encapsulation film (S400), the preliminary organic layer P-OL may be irradiated with ultraviolet (UV) rays, and the acrylate-based monomer BMR may be photopolymerized and photocured to form the organic encapsulation film OL. The acrylate-based monomer BMR may be photopolymerized and photocured to form a base part BMP including a polymer material.

The organic encapsulation film OL may include the base part BMP formed through UV curing, and the organic acid additive AGT included in the organic encapsulation film OL in the form of a thin film. The organic acid additive AGT may be included in the organic encapsulation film OL until volatilization is initiated.

The second inorganic encapsulation film IOL2 may be formed on the organic encapsulation film OL. The organic encapsulation film OL may be provided between the inorganic encapsulation films IOL1 and IOL2, and a stacked structure of the first inorganic encapsulation film IOL1, the organic encapsulation film OL, and the second inorganic encapsulation film IOL2 may effectively protect the light emitting element ED.

Although an encapsulation layer in the display panel according to one or more embodiments manufactured by the steps in FIGS. 12B to 12E is illustrated as including the first inorganic encapsulation film IOL1, the organic encapsulation film OL, and the second inorganic encapsulation film IOL2, embodiments of the present disclosure are not limited thereto, and an encapsulation layer TFE may be formed to further include at least one inorganic encapsulation film and at least one organic encapsulation film.

FIG. 12E is a view illustrates the performing of the heat treatment (S600) as an example. The heat treatment (S600) may be performed after the encapsulation layer TFE is formed. In the performing of the heat treatment (S600), the heat treatment may be performed at a temperature equal to or higher than a volatile onset temperature of the organic acid additive AGT included in the organic encapsulation film OL. In the performing of the heat treatment (S600), the heat treatment may be performed at a temperature of about 80° C. to about 120° C. As the heat treatment is performed at the temperature of about 80° C. to about 120° C., the organic acid additive AGT may be sufficiently volatilized and also the other components of the display panel may be prevented or reduced from be damaged by heat.

The performing of the heat treatment (S600) may include volatilizing the organic acid additive AGT to move the organic acid additive AGT toward the emission layer EML and the electron transport region ETR.

The performing of the heat treatment (S600) may include passivating an oxygen vacancy defect in the emission layer EML and/or an oxygen vacancy defect in the electron transport region ETR by using a carboxyl derivative derived from the organic acid additive AGT. For example, the performing of the heat treatment (S600) may include at least one of coupling the carboxyl derivative to a quantum dot having the oxygen vacancy defect to form a modified quantum dot, or coupling the carboxyl derivative to a metal oxide particle having the oxygen vacancy defect to form a modified metal oxide particle.

After the performing of the heat treatment (S600), the organic acid additive AGT may be volatilized and moved MVD from the organic encapsulation film OL to the emission layer EML or the electron transport region ETR, and the carboxyl derivative derived from the organic acid additive AGT may be coupled to at least a portion of a material of the emission layer EML or a material of the electron transport region ETR.

In the method for manufacturing the display panel according to one or more embodiments (S10), the organic acid additive AGT may be included in the organic encapsulation film OL in the forming of the organic encapsulation film (S400), and, in the performing of the heat treatment (S600), the organic acid additive AGT may be moved in a fume state to at least one of the emission layer EML or the electron transport region ETR, and the carboxyl derivative derived from the organic acid additive AGT may be coupled to at least one of the quantum dots (e.g., a portion of the quantum dots) of the emission layer EML or the metal oxide particles (e.g., a portion of the metal oxide particles) of the electron transport region ETR.

The method for manufacturing the display panel according to one or more embodiments may include steps (e.g., acts or tasks) of providing the organic layer mixture including the organic acid additive and the acrylate-based monomer and UV curing the organic layer mixture to form the organic encapsulation film, and performing the heat treatment after the forming of the encapsulation layer. Accordingly, the organic acid additive that is an aging agent may be provided to be included in the resulting thin film, thereby minimizing or reducing a damage to the light emitting element caused by an acid additive compared to a case in which the organic acid additive is directly provided to the light emitting element. Moreover, only a limited amount of the organic acid additive may be included in the organic encapsulation film to prevent or reduce the organic acid additive from being excessively (or substantially) provided, and thus a chemical reaction of the organic acid additive with other components of the display panel may be minimized or reduced. Accordingly, the display panel according to one or more embodiments may exhibit excellent or suitable reliability characteristics.

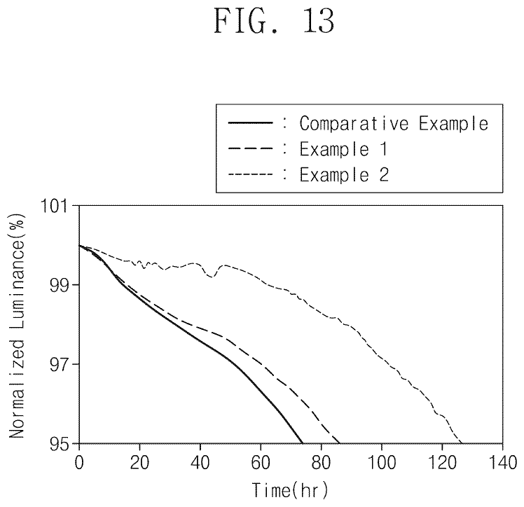

FIG. 13 is a graph illustrating luminance characteristics of one or more embodiments and a comparative example. FIG. 13 relatively illustrates changes in luminance over time. On the basis of 100% of an initial luminance, a decrease in luminance over time is expressed by a normalized luminance (%).

In FIG. 13, the Comparative Example is related to a light emitting element in which the organic acid additive C1, the evaluations results thereof shown in Table 1, was in an organic encapsulation film, and Examples 1 and 2 are each related to a light emitting element in which the organic acid additive A12, the evaluations results thereof shown in Table 1, was included in an organic encapsulation film. In the Comparative Example and the Examples, monomer compounds used for the forming of the organic encapsulation film were used by mixing the acrylate-based monomers M1 and M2 described above. A mixture of M1 and M2 at a ratio of 6.5:3.5 was used in the Comparative Example and the Examples.

In the Comparative Example, C1 was included in an amount of about 0.35 wt % with respect to the acrylate-based monomer in the organic encapsulation film. The amount of about 0.35 wt % corresponds to the maximum solubility with respect to the used monomer compounds.

In Example 1, A12 was included in an amount of about 1 wt % with respect to the acrylate-based monomer in the organic encapsulation film, and in Example 2, A12 was included in an amount of about 5 wt % with respect to the acrylate-based monomer in the organic encapsulation film.

Referring to results in FIG. 13, the Example embodiments showed smaller changes in luminance over time than the Comparative Example. Thus, it may be confirmed that the Example embodiments each including the organic acid additive according to one or more embodiments described above exhibit excellent or suitable element characteristics compared to the organic acid additive according to the comparative example. In addition, as a result of the comparison between Example 1 and Example 2, it may be confirmed that when A12 was included in an amount of about 5 wt % with respect to the acrylate-based monomer in the organic encapsulation film, a decrease in luminance upon initial driving was significantly improved, and high luminance characteristics were maintained for a long time.

A display panel according to one or more embodiments may include a light emitting element in which at least one of an emission layer or an electron transport region includes a material in which a defect is passivated by an organic acid additive provided from an organic encapsulation film, thereby exhibiting excellent or suitable efficiency and long lifespan characteristics. In addition, in the display panel according to one or more embodiments, the organic acid additive may be provided in a state of being included in a thin film that is the organic encapsulation film, thereby minimizing or reducing a damage to the light emitting element caused by an acid additive compared to a case in which the organic acid additive is directly provided to the light emitting element.

An electronic device according to one or more embodiments may include the display panel according to one or more embodiments which displays an image, and may thus exhibit excellent or suitable display quality, long lifespan characteristics, and excellent or suitable reliability characteristics. A method for manufacturing the display panel according to one or more embodiments may include steps (e.g., acts or tasks) of providing an organic layer mixture including an organic acid additive and an acrylate-based monomer and UV curing the organic layer mixture to form an organic encapsulation film, and performing a heat treatment after forming an encapsulation layer, and the organic acid additive that is an aging agent may be provided to be included in the thin film. Accordingly, the display panel having excellent or suitable efficiency and lifespan and with improved reliability may be manufactured.

In the display panel and the electronic device including the display panel according to one or more embodiments of the present disclosure, the encapsulation layer arranged on the light emitting element may include the organic acid additive, and the defective portion in the emission layer and/or the defective portion in the electron transport region may be passivated by the organic acid additive, thereby exhibiting the excellent or suitable luminance efficiency and long lifespan characteristics.

The electronic device according to one or more embodiments of the present disclosure may include the light emitting element with the element performance improved using the organic acid additive included in the encapsulation layer, thereby exhibiting the improved display quality and reliability characteristics.

The method for manufacturing the display panel according to one or more embodiments of the present disclosure may include providing the organic acid additive having the carboxyl group into the encapsulation layer within the thin film and then performing the heat treatment, so that the defect in the light emitting element is passivated by the organic acid additive. Accordingly, the method may be used for the manufacture of the display panel having the improved element characteristics.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value. Also, it should be understood that, even if the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

In the context of the present application and unless otherwise defined, the terms “use,” “using,” and “used” may be considered synonymous with the terms “utilize,” “utilizing,” and “utilized,” respectively.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this disclosure, including the claims, to expressly recite any sub-range subsumed within the ranges expressly recited herein.

The light emitting element, the display device, the display panel, the electronic device/apparatus, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

In the present disclosure, each suitable feature of the various embodiments of the disclosure may be combined or combined with each other, partially or entirely, and may be technically interlocked and operated in various suitable ways, and each embodiment may be implemented independently of each other or in conjunction with each other in any suitable manner unless otherwise stated or implied.

In the above, description has been made with reference to one or more embodiments of the disclosure, but those skilled or of ordinary skill in the art may understand that one or more suitable modifications and changes may be made to the disclosure insofar as such modifications and changes do not depart from the spirit and technical scope of the present disclosure set forth in the appended claims.

Therefore, the technical scope of the present disclosure is not to be limited to the content stated in the detailed description of the disclosure, but should be determined by the claims and equivalents thereof.

What is claimed is:

1. A display panel, comprising:
a light emitting element comprising a first electrode, a hole transport region, an emission layer, an electron transport region, and a second electrode, which are stacked in sequence; and
an encapsulation layer on the light emitting element and comprising at least one inorganic encapsulation film and at least one organic encapsulation film,
wherein the emission layer comprises a plurality of quantum dots, and the electron transport region comprises a plurality of metal oxide particles, and
wherein a carboxyl derivative is coupled to at least a portion of the quantum dots and/or at least a portion of the metal oxide particles.

2. The display panel of claim 1, wherein the electron transport region comprises a modified metal oxide particle in which the carboxyl derivative is coupled to an outer edge of the metal oxide particle.

3. The display panel of claim 1, wherein each of the quantum dots of the emission layer comprises a core and a shell around the core, and
wherein the emission layer comprises a modified quantum dot comprising the carboxyl derivative coupled to the shell.

4. The display panel of claim 1, wherein the carboxyl derivative is derived from an organic acid additive represented by any one selected from among A1 to A12: 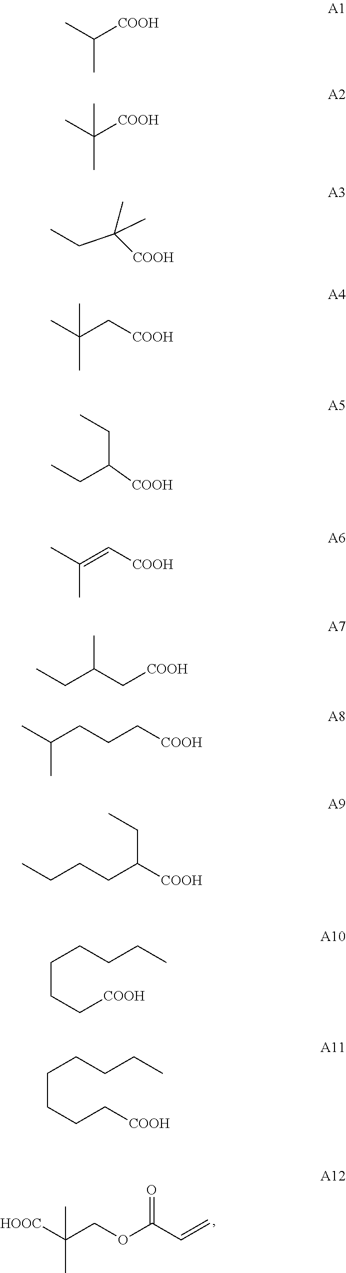
and
wherein the at least one organic encapsulation film further comprises the organic acid additive.

5. The display panel of claim 1, wherein the at least one organic encapsulation film comprises a polymer base part polymerized from an organic layer mixture comprising an acrylate-based monomer and an organic acid additive,
wherein the emission layer comprises a modified quantum dot to which the carboxyl derivative derived from the organic acid additive is coupled, and
wherein the electron transport region comprises a modified metal oxide particle to which the carboxyl derivative derived from the organic acid additive is coupled.

6. The display panel of claim 1, wherein the encapsulation layer comprises:
a first inorganic encapsulation film directly on the light emitting element;
an organic encapsulation film on the first inorganic encapsulation film; and
a second inorganic encapsulation film on the organic encapsulation film.

7. An electronic device, comprising:
a display device comprising a display panel configured to display an image,
wherein the display panel comprises:
a base layer;
a circuit layer on the base layer;
a display layer on the circuit layer and comprising a plurality of light emitting elements; and
an encapsulation layer on the display layer and comprising at least one inorganic encapsulation film and at least one organic encapsulation film,
wherein each of the light emitting elements comprises a first electrode, a hole transport region, an emission layer, an electron transport region, and a second electrode, which are stacked in sequence,
wherein the emission layer comprises a plurality of quantum dots, and the electron transport region comprises a plurality of metal oxide particles, and
wherein a carboxyl derivative is coupled to at least a portion of the quantum dots and/or at least a portion of the metal oxide particles.

8. The electronic device of claim 7, wherein the at least one organic encapsulation film comprises a polymer base part polymerized from an organic layer mixture comprising an acrylate-based monomer and an organic acid additive,
wherein the emission layer comprises a modified quantum dot to which the carboxyl derivative derived from the organic acid additive is coupled, and
wherein the electron transport region comprises a modified metal oxide particle to which the carboxyl derivative derived from the organic acid additive is coupled.

9. The electronic device of claim 8, wherein the organic acid additive has an acid dissociation constant (pKa) of 4.8 or higher, and has a volatile onset temperature of lower than 90° C., and
wherein a difference (Ra) in Hansen solubility parameter between the organic acid additive and the acrylate-based monomer is less than 12.

10. A method, comprising:
forming a light emitting element in which a first electrode, a hole transport region, an emission layer, an electron transport region, and a second electrode are stacked in sequence;
forming a first inorganic encapsulation film on the light emitting element;
applying an organic layer mixture onto the first inorganic encapsulation film, the organic layer mixture comprising an organic acid additive having at least one carboxyl group, and an acrylate-based monomer;
ultraviolet curing the organic layer mixture to form an organic encapsulation film;
forming a second inorganic encapsulation film on the organic encapsulation film; and
performing a heat treatment at a temperature of 80° C. to 120° C.,
wherein the method is a method for manufacturing a display panel.

11. The method of claim 10, wherein the organic acid additive has an acid dissociation constant (pKa) of 4.8 or higher, and has a volatile onset temperature of lower than 90° C.

12. The method of claim 11, wherein a difference (Ra) in Hansen solubility parameter between the organic acid additive and the acrylate-based monomer is less than 12.

13. The method of claim 10, wherein the organic acid additive is represented by one selected from among A1 to A12:

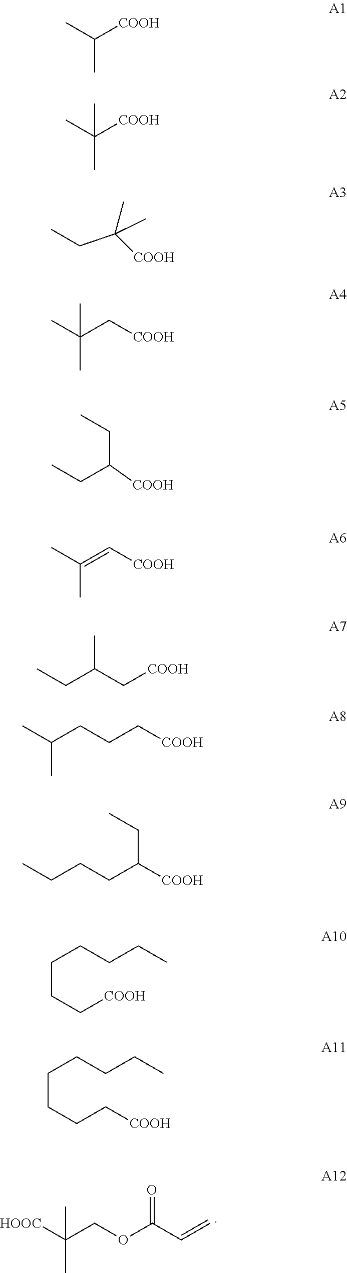

14. The method of claim 10, wherein the acrylate-based monomer comprises at least one of monomer compound M1 or monomer compound M2:

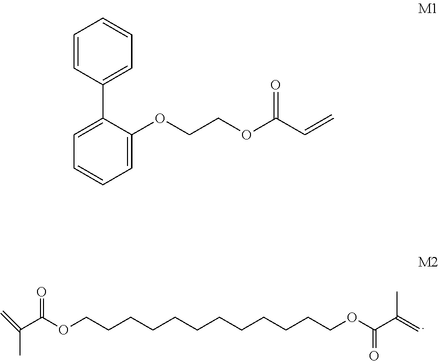

15. The method of claim 10, wherein the performing of the heat treatment comprises volatilizing the organic acid additive to move the organic acid additive toward the emission layer and the electron transport region.

16. The method of claim 10, wherein an amount of the organic acid additive is 5 wt % to 30 wt % on the basis of a weight of the acrylate-based monomer in the organic layer mixture.

17. The method of claim 10, wherein, in the forming of the light emitting element,
the emission layer comprises a plurality of quantum dots, each of which comprises a core and a shell around the core, and
the electron transport region comprises a plurality of metal oxide particles, and
wherein at least a portion of the quantum dots and/or at least a portion of the metal oxide particles have an oxygen vacancy defect.

18. The method of claim 17, wherein the performing of the heat treatment comprises passivating the oxygen vacancy defect by utilizing a carboxyl derivative derived from the organic acid additive.

19. The method of claim 17, wherein the performing of the heat treatment comprises at least one of:
coupling a carboxyl derivative derived from the organic acid additive to the quantum dot having the oxygen vacancy defect to form a modified quantum dot; or
coupling a carboxyl derivative derived from the organic acid additive to the metal oxide particle having the oxygen vacancy defect to form a modified metal oxide particle.

20. The method of claim 17, wherein,
in the forming of the organic encapsulation film, the organic acid additive is comprised in the organic encapsulation film, and
in the performing of the heat treatment, the organic acid additive is moved in a fume state to at least one of the emission layer or the electron transport region, and a carboxyl derivative derived from the organic acid additive is coupled to at least one of a portion of the quantum dots of the emission layer or a portion of the metal oxide particles of the electron transport region.
